(19) United States
(12) Patent Application Publication
(10) Pub. No.: US 2015/0111049 A1
(43) Pub. Date: Apr. 23, 2015

(54) ENTRY SHEET FOR DRILLING USE

(71) Applicant: MITSUBISHI GAS CHEMICAL COMPANY, INC., Tokyo (JP)

(72) Inventors: Yousuke Matsuyama, Yamagata (JP); Takuya Hasaki, Yamagata (JP)

(21) Appl. No.: 14/383,630

(22) PCT Filed: Mar. 5, 2013
(86) PCT No.: PCT/JP2013/001370

§ 371 Date: Sep. 8, 2014

(30) Foreign Application Priority Data
Mar. 9, 2012 (JP) 2012-053570

(51) Int. Cl. H05K 3/00

(52) U.S. Cl. CPC H05K 3/0047; H05K 2203/0214
USPC 428/464; 428/457; 428/458; 428/461; 428/337; 428/339

(57) ABSTRACT

The present invention relates to an entry sheet for drilling use, which exhibits excellent hole position accuracy even when transported at ambient temperature for a long time and/or stored under a thermal environment having a higher temperature than in Japan, more specifically to an entry sheet for drilling use for a laminated board or a multi-layered board comprising a metallic support foil and a layer of water-soluble resin composition formed on at least one surface of the metallic support foil, wherein the water-soluble resin composition comprises a water-soluble resin, a water-soluble lubricant and a linear unsaturated fatty acid salt, the layer of water-soluble resin composition is formed by cooling from a cooling start temperature of 120° C. to 160° C. to a cooling end temperature of 25° C. to 40° C. within 60 seconds at a cooling rate of not less than 1.5° C./sec, the water-soluble resin composition has a degree of crystallinity of not less than 1.2, the layer of water-soluble resin composition has a standard deviation σ of surface hardness of not more than 2, and a surface hardness of not less than 8.5 to not more than 25 N/mm².

### TECHNICAL FIELD

This invention relates to an entry sheet for drilling use, which is used in drilling a laminated board or a multi-layered board.

### RELATED ART

As a method for drilling a laminated board or a multi-layered board used in a printed wiring board, a method of superimposing one or a plurality of laminated boards or multi-layered boards, disposing on the top thereof a single aluminum foil or a sheet having a resin composition layer formed on the aluminum foil surface (hereinafter, this “sheet” will be referred to as an “entry sheet for drilling use”) as a reinforcing board, and drilling is generally adopted. It should be noted that although a copper clad laminated board is generally used as a laminated board, it may be a “laminated board” with no copper foil on the outer layer.

In recent years, along with demand for improvement in reliability and development in high densification of printed wiring boards, high quality drilling of laminated boards or multi-layered boards with improved hole position accuracy, reduced hole wall roughness and the like has been required. In order to respond to this requirement, a drilling method using a sheet comprising a water-soluble resin such as polyethylene glycol (e.g., see Patent Document 1), a lubricant sheet for drilling use having a water-soluble resin layer formed on a metallic support foil (e.g., see Patent Document 2), an entry sheet for drilling use having a water-soluble resin layer formed on an aluminum foil having a thermosetting resin thin film formed thereon (e.g., see Patent Document 3), a lubricant sheet for drilling use having a non-halogen colorant contained in a lubricant resin composition (e.g., see Patent Document 4), and the like have been proposed and implemented.

Moreover, the recent trends include the following characteristics.

Firstly, high densification of printed wiring boards is continuing and conduction reliability of drilled holes on laminated boards or multi-layered boards has been required. More specifically, excellent hole position accuracy is needed.

Secondly, countries of manufacturing printed wiring boards have been shifted, with motives for cost reduction and industrial agglomeration with semiconductors, from Japan, through Taiwan and South Korea, to other Asian countries including China at the center, Brazil and the like, and the geographical transition continues.

Thirdly, in Taiwan and South Korea, manufacturers of entry sheets for drilling use have risen to sudden eminence, and a market environment of competing against these local manufacturers has gradually arisen.

Fourthly, as a semiconductor related industry, demand for entry sheets for drilling use largely fluctuates, the stock may pile in supply chains when the demand sharply declines, and it may be stored until the demand recovers and then used. Moreover, with high densification of printed wiring boards, excellent hole position accuracy has been required even after being stored.

With such trends as background, circumstances of entry sheets for drilling use cannot avoid changing from short time transport such as domestic transport and transport by air to long time transport at ambient temperature such as container transport at ambient temperature by sea. Also, they may be stored under environment with a higher temperature than in Japan. Therefore, excellent hole position accuracy has been required to be exhibited even after such a temperature history of transport or storage. In other words, development of an entry sheet for drilling use, which exhibits excellent hole position accuracy even after a higher temperature history than conventional has been earnestly desired.

### PRIOR ART DOCUMENTS

### Patent Documents

Patent Document 1: JP-A-H4-92494
Patent Document 2: JP-A-H5-169400
Patent Document 3: JP-A-2003-136485
Patent Document 4: JP-A-2004-230470

### SUMMARY OF THE INVENTION

### Problem to be Solved by the Invention

The object of the invention is, therefore, to provide an entry sheet for drilling use, which exhibits excellent hole position accuracy even when transported at ambient temperature for a long time and/or stored under a thermal environment having a higher temperature than in Japan.

### Means for Solving the Problem

The inventors have, as a result of various considerations for solving the above problem, found out that by adding a linear unsaturated fatty acid salt in a water-soluble resin composition formed on the surface of an entry sheet for drilling use, the degree of crystallinity can be increased, and excellent hole position accuracy can be exhibited even after a thermal deterioration acceleration test to solve the above problem. More specifically, the invention is as follows.

[1] An entry sheet for drilling use for a laminated board or a multi-layered board comprising a metallic support foil and a layer of water-soluble resin composition formed on at least one surface of the metallic support foil, wherein

the water-soluble resin composition comprises a water-soluble resin, a water-soluble lubricant and a linear unsaturated fatty acid salt,
the layer of water-soluble resin composition is formed by coating on the metallic support foil, a hot melt of the water-soluble resin composition, or coating on the metallic support foil, a solution containing the water-soluble resin composition and drying it, and then cooling it from a cooling start temperature of 120° C. to 160° C. to a cooling end temperature of 25° C. to 40° C. within 60 seconds at a cooling rate of not less than 1.5° C./sec,
the water-soluble resin composition has a degree of crystallinity of not less than 1.2, and
the layer of water-soluble resin composition has a standard deviation σ of surface hardness of not more than 2, and a surface hardness of not less than 8.5 N/mm² to not more than 25 N/mm².

[2] An entry sheet for drilling use according to the above item [1], wherein the linear unsaturated fatty acid salt has a carbon number of not less than 3 to not more than 20.

[3] An entry sheet for drilling use according to the above item [1], wherein the linear unsaturated fatty acid salt is one kind or more selected from the group consisting of a sorbic acid salt, an oleic acid salt and a linoleic acid salt.

[4] An entry sheet for drilling use according to the above item [1], wherein the linear unsaturated fatty acid salt is an alkali metal salt.

[5] An entry sheet for drilling use according to the above item [1], wherein the water-soluble resin is one kind or more selected from the group consisting of polyethylene oxide, polypropylene oxide, sodium polyacrylate, polyacrylamide, polyvinylpyrrolidone, a cellulose derivative, polytetramethylene glycol and a polyester of polyalkylene glycol, with a weight average molecular weight (Mw) of not less than 60,000 to not more than 400,000.

[6] An entry sheet for drilling use according to the above item [1], wherein the water-soluble lubricant is one kind or more selected from the group consisting of polyethylene glycol, polypropylene glycol, monoethers of polyoxyethylene, polyoxyethylene monostearate, polyoxyethylene sorbitan monostearate, polyglycerin monostearates, and a polyoxyethylene propylene copolymer, with a weight average molecular weight (Mw) of not less than 500 to not more than 25,000.

[7] An entry sheet for drilling use according to the above item [1], wherein in a total of 100 parts by weight of water-soluble resin mixture comprising the water-soluble resin and the water-soluble lubricant, the content of the water-soluble resin is 3 parts by weight to 80 parts by weight, and the content of the water-soluble lubricant is 20 parts by weight to 97 parts by weight.

[8] An entry sheet for drilling use according to the above item [1], wherein the added amount of the linear unsaturated fatty acid salt is not less than 0.01 parts by weight to not more than 20 parts by weight based on a total of 100 parts by weight of the water-soluble resin and the water-soluble lubricant.

[9] An entry sheet for drilling use according to the above item [1], wherein the water-soluble resin composition further contains sodium formate.

[10] An entry sheet for drilling use according to the above item [1], wherein the added amount of the sodium formate is not less than 0.01 parts by weight to not more than 1.5 parts by weight based on a total of 100 parts by weight of the water-soluble resin and the water-soluble lubricant.

[11] An entry sheet for drilling use according to the above item [1], wherein the water-soluble resin composition has a solidifying temperature of not less than 30° C. to not more than 70° C.

[12] An entry sheet for drilling use according to the above item [1], for use in drilling with a drill bit diameter of not less than 0.05 mmφ to not more than 0.3 mmφ, in drilling a laminated board or a multi-layered board.

[13] An entry sheet for drilling use according to the above item [1], wherein the metallic support foil has a thickness of not less than 0.05 mm to not more than 0.5 mm.

[14] An entry sheet for drilling use according to the above item [13], wherein the metallic support foil is an aluminum foil having a resin membrane with a thickness of 0.001 to 0.02 mm attached thereto.

[15] An entry sheet for drilling use according to the above item [1], wherein the layer of water-soluble resin composition has a thickness of not less than 0.01 mm to not more than 0.3 mm.

### Effect of the Invention

In the entry sheet for drilling use of the invention, hole position accuracy after a thermal deterioration acceleration test, for example a thermal deterioration acceleration test under air atmosphere at 50° C. for one hour, at 50° C. for one week, at 50° C. for one month and at 55° C. for one week is not more than 25 μm, and the change ratio of hole position accuracy after the thermal deterioration test is within +10%, which is excellent. More specifically, the entry sheet for drilling use of the invention has an effect of improving hole position accuracy, even after being transported at ambient temperature for a long time and/or stored under a thermal environment having a higher temperature than in Japan, as compared to before the transport and/or storage, or reducing thermal deterioration of hole position accuracy. Thereby, highly densified drilling in response to globalization and demand fluctuation has become possible.

### BRIEF DESCRIPTION OF DRAWINGS

The invention will be described with reference to the accompanying drawings, wherein:

FIG. 1 is a graph of degree of crystallinity (untreated) vs hole position accuracy (after a thermal deterioration acceleration test at 50° C. for one hour) of entry sheets in Examples and Comparative Examples;

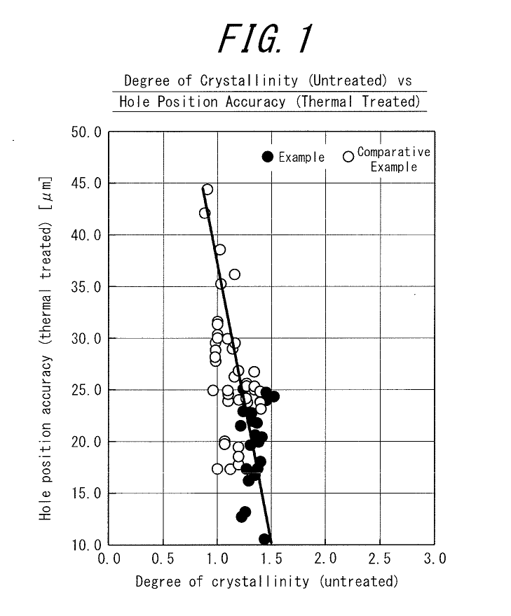

FIG. 2 is a graph of standard deviation σ of surface hardness (after a thermal deterioration acceleration test at 50° C. for one hour) vs hole position accuracy (after a thermal deterioration acceleration test at 50° C. for one hour) of entry sheets in Examples and Comparative Examples;

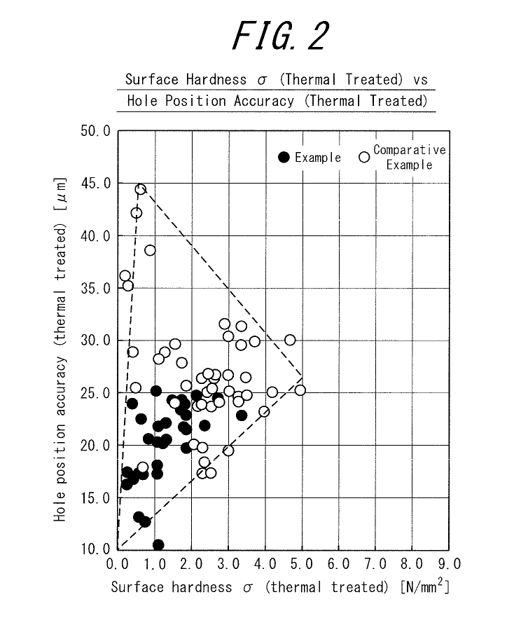

FIG. 3 is a graph of hole position accuracy Δ vs degree of crystallinity (untreated) of entry sheets in Examples and Comparative Examples; and

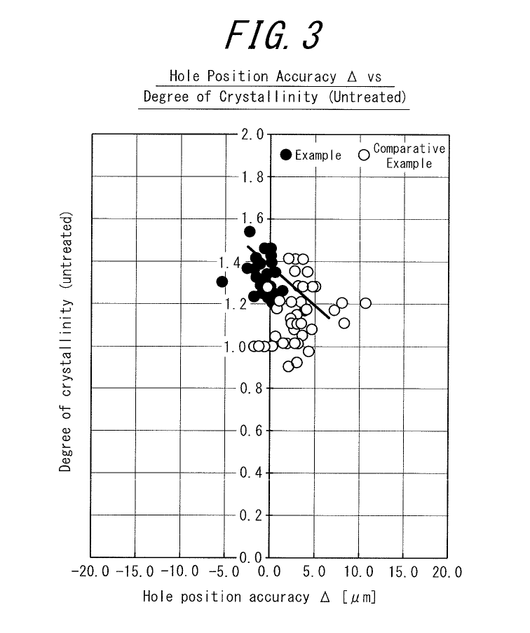

FIG. 4 is a graph of hole position accuracy Δ vs surface hardness (after a thermal deterioration acceleration test at 50° C. for one hour) of entry sheets in Examples and Comparative Examples.

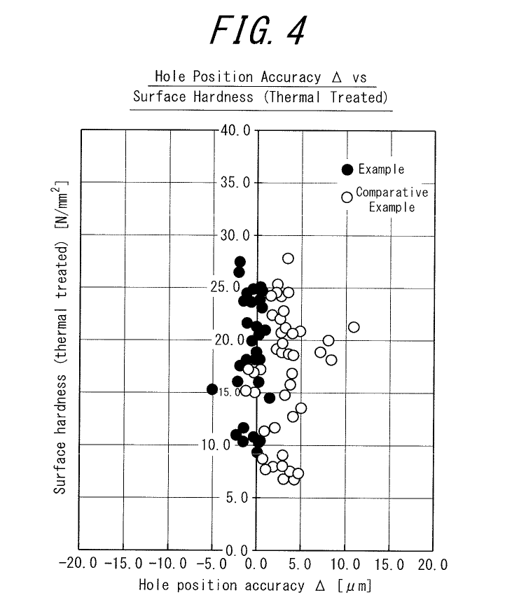

### MODE FOR CARRYING OUT THE INVENTION

The invention is an entry sheet for drilling use for a laminated board or a multi-layered board comprising a metallic support foil and a layer of water-soluble resin composition formed on at least one surface of the metallic support foil, wherein the water-soluble resin composition comprises a water-soluble resin, a water-soluble lubricant and a linear unsaturated fatty acid salt, the layer of water-soluble resin composition is formed by coating on the metallic support foil, a hot melt of the water-soluble resin composition, or coating on the metallic support foil, a solution containing the water-soluble resin composition and drying it, and then cooling it from a cooling start temperature of 120° C. to 160° C. to a cooling end temperature of 25° C. to 40° C. within 60 seconds at a cooling rate of not less than 1.5° C./sec, the water-soluble resin composition has a degree of crystallinity of not less than 1.2, and the layer of water-soluble resin composition has a standard deviation σ of surface hardness of not more than 2, and a surface hardness of not less than 8.5 N/mm² to not more than 25 N/mm².

The water-soluble resin in the invention has a relatively high molecular weight. Since film formability is required to form the water-soluble resin composition in a sheet state, a water-soluble resin is contained to give film formability to the water-soluble resin composition, and the molecular structure does not matter but the weight average molecular weight (Mw) is preferably not less than 60,000 to not more than 400,000. For example, the water-soluble resin is preferable to be one kind or more selected from the group consisting of polyethylene oxide, polypropylene oxide, sodium polyacrylate, polyacrylamide, polyvinylpyrrolidone, a cellulose derivative, polytetramethylene glycol, and a polyester of polyalkylene glycol. Cellulose derivatives include carboxymethyl cellulose, hydroxyethyl cellulose and the like. Here, the polyester of polyalkylene glycol is a condensate obtained by reacting polyalkylene glycol with a bibasic acid. Examples of polyalkylene glycol include glycols such as polyethylene glycol, polypropylene glycol, polytetramethylene glycol, and a copolymer thereof. Also, bibasic acids include a phthalic acid, an isophthalic acid, a terephthalic acid, a sebacic acid and the like. Moreover, it may be a polycarboxylic acid such as a pyromellitic acid partially esterificated to have two carboxyl groups. It may be an acid anhydride. Although it is also possible to use one kind or two kinds or more mixed accordingly, it is more preferable to be polyethylene oxide (PEO).

The water-soluble lubricant in the invention has a relatively low molecular weight. The water-soluble lubricant is contained to give lubricability to the water-soluble resin composition, and the molecular structure does not matter but the weight average molecular weight (Mw) is preferably not less than 500 to not more than 25,000. Water-soluble lubricants include, specifically: polyethylene glycol, polypropylene glycol; monoethers of polyoxyethylene such as polyoxyethylene oleylether, polyoxyethylene cetylether, polyoxyethylene stearylether, polyoxyethylene laurylether, polyoxyethylene nonylphenylether, polyoxyethylene octylphenylether; polyoxyethylene monostearate, polyoxyethylene sorbitan monostearate; polyglycerin monostearates such as hexaglycerin monostearate, decahexaglycerin monostearate; a polyoxyethylene propylene copolymer and the like. Although it is also possible to use one kind or two kinds or more mixed accordingly, it is more preferable to be polyethylene glycol (PEG).

The linear unsaturated fatty acid salt refers to a compound having one or more dissociable hydrogen ions contained in a linear unsaturated fatty acid substituted with a cation such as a metal ion and an ammonium ion. The linear unsaturated fatty acid constituting the linear unsaturated fatty acid salt is not particularly limited, as long as it is a fatty acid with a linear carbon chain having one or more carbon-carbon unsaturated bonds within its molecule. The carbon-carbon unsaturated bond is preferable to be a carbon-carbon double bond.

The linear unsaturated fatty acid salt has a carbon number of preferably not less than 3 to not more than 20, more preferably not less than 6 to not more than 18. Preferred linear unsaturated fatty acid salts include, for example, a sorbic acid (carbon number 6), an oleic acid (carbon number 18), a linoleic acid (carbon number 18) and the like.

Moreover, the linear unsaturated fatty acid salt is preferable to be an alkali metal salt or an alkali earth metal salt. Furthermore, from perspectives of dispersability in a resin composition, dissolvability in water, easiness of handling and obtaining and the like, the linear unsaturated fatty acid salt is preferable to be a potassium salt, a sodium salt or a calcium salt.

In addition, among linear unsaturated fatty acid salts, sodium oleate is particularly preferable.

The linear unsaturated fatty acid salt in the invention has, by containing a linear unsaturated fatty acid salt in a resin composition layer of an entry sheet for drilling use, a function of improving thermal stability of the resin composition. Here, although thermal stability may be improved by containing other substances commonly referred to as a thermal stabilizer or an antioxidant in the resin composition, these substances do not have any effect of improving hole position accuracy of an entry sheet for drilling use. On the other hand, containing a linear unsaturated fatty acid salt in a resin composition of an entry sheet for drilling use has a function of improving properties as an entry sheet for drilling use, by increasing the degree of crystallinity of the resin composition and making variability in resin composition layer surface hardness small.

Regarding the contents of the water-soluble resin and the water-soluble lubricant in the invention, in a total of 100 parts by weight of water-soluble resin mixture comprising the water-soluble resin and the water-soluble lubricant, the water-soluble resin is preferably within a range of 3 parts by weight to 80 parts by weight, and the water-soluble lubricant within a range of 20 parts by weight to 97 parts by weight. With less than 3 parts by weight of the water-soluble resin, sheet formability is poor, while with more than 80 parts by weight of the water-soluble resin, resins twining around a drill bit increase, which is not preferable.

In the invention, it is important that the degree of crystallinity of a water-soluble resin composition is not less than 1.2. As described above, the linear unsaturated fatty acid salt has a function effect of increasing the degree of crystallinity of the water-soluble resin composition of the entry sheet for drilling use of the invention, and improving hole position accuracy. Moreover, the inventors discovered that it shows a characteristic function effect of particularly improving hole position accuracy, or reducing thermal deterioration of hole position accuracy, after a thermal deterioration acceleration test, for example a thermal deterioration acceleration test under air atmosphere. Many experiment cases where the standard deviation σ of the surface hardness of a water-soluble resin composition layer becomes further smaller after a thermal deterioration acceleration test by adding a linear unsaturated fatty acid salt, and experiment cases where the standard deviation σ of the surface hardness is maintained at a low level even after a thermal deterioration acceleration test were observed. Although it depends on other compositions and process conditions, maintaining a uniformity of the surface hardness of a water-soluble resin composition layer at a high level after a thermal deterioration acceleration test, or improving the uniformity is a characteristic function of the linear unsaturated fatty acid salt. The entry sheet for drilling use of the invention is, with this effect as one factor, believed to have an effect of reducing thermal deterioration of hole position accuracy or improving hole position accuracy, even when transported at ambient temperature for a long time and/or stored under a thermal environment having a higher temperature than in Japan.

Herein, the above thermal deterioration acceleration test refers to a test of being left under air atmosphere at a higher temperature than ambient temperature for a given time. The temperature is set accordingly as higher than the solidifying temperature of the water-soluble resin composition, lower than the melting point.

The condition setting of the above thermal deterioration acceleration test will be described further specifically below. The water-soluble resin composition contained in the entry sheet for drilling use of the invention has a melting point of around approximately 60° C., and when it reaches a temperature above that, the form as a layer of water-soluble resin may not be maintained. Therefore, the test temperature of a thermal deterioration acceleration test is required to be set as lower than the melting point of a water-soluble resin composition, higher than ambient temperature. Moreover, for the test period of a thermal deterioration acceleration test, it is required to consider the actual transportation. More specifically, for the temperature and the period of a thermal deterioration acceleration test, it is possible to confirm the effect of thermal deterioration stability of the entry sheet for drilling use of the invention by conducting an evaluation under four conditions: i) 50° C., one hour; ii) 50° C., one week; iii) 50° C., one month; iv) 55° C., one week. With the test temperature condition of less than 50° C., influence of thermal deterioration to a water-soluble resin composition layer is small and the effect of thermal stability is difficult to compare, while with that of not less than 60° C., the form of a water-soluble resin composition layer may not be maintained as described above, and properties as an entry sheet for drilling use may become unable to be evaluated. Moreover, the above conditions for a thermal deterioration acceleration test have been set in consideration of the temperature and the period in a container on the actual sea route. For example, regarding the environment of transport on sea route, the period required from the East Coast of the United States to Japan is about a month, the temperature within a container in July to August is not more than 40° C., the period required from India to Japan is about a month, the temperature within a container in September to October is about 50° C., the period required from Malaysia to Japan is about 15 days, the temperature within a container in August is about 40° C.

The added amount of a linear unsaturated fatty acid salt is preferable to be not less than 0.01 parts by weight to not more than 20 parts by weight based on a total of 100 parts by weight of the water-soluble resin and the water-soluble lubricant. When the added amount of a linear unsaturated fatty acid salt is less than 0.01 parts by weight, the effect is difficult to obtain. On the other hand, when the added amount of a linear unsaturated fatty acid salt is more than 20 parts by weight, it becomes difficult to uniformly disperse the linear unsaturated fatty acid salt in a water-soluble resin composition, and the linear unsaturated fatty acid salt may precipitate from the water-soluble resin composition layer surface. When the linear unsaturated fatty acid salt precipitates and contacts a drill bit, hole position accuracy may deteriorate, a drill bit may break, and the linear unsaturated fatty acid salt may remain within a hole wall after drilling. Therefore, the added amount of a linear unsaturated fatty acid salt is preferable to be not less than 0.01 parts by weight to not more than 20 parts by weight, and desirable to be optimized accordingly. For example, the added amount of a linear unsaturated fatty acid salt is more preferably not less than 0.1 parts by weight, further preferably not less than 0.2 parts by weight to not more than 18 parts by weight, further more preferably not less than 1 parts by weight to not more than 16 parts by weight, even further more preferably not less than 4 parts by weight to not more than 12 parts by weight.

The water-soluble resin composition used in the entry sheet for drilling use of the invention is preferable to further contain sodium formate. The sodium formate is a nucleating agent which has, by adding it to a water-soluble resin composition, a function of increasing the degree of crystallinity of the water-soluble resin composition, and contributing to hole position accuracy improvement. The added amount of sodium formate is preferably not less than 0.01 parts by weight to not more than 1.5 parts by weight based on a total of 100 parts by weight of the water-soluble resin and the water-soluble lubricant. When the added amount of sodium formate is less than 0.01 parts by weight, a function of increasing the degree of crystallinity is difficult to exhibit. Therefore, the added amount of sodium formate is preferably not less than 0.01 parts by weight, further preferably not less than 0.05 parts by weight, even more preferably not less than 0.1 parts by weight, particularly preferably not less than 0.25 parts by weight to not more than 1.0 parts by weight. On the other hand, when the added amount of sodium formate is more than 1.5 parts by weight, sodium formate precipitates to the surface of the water-soluble resin composition layer, and a defect may occur, which is not preferable.

The linear unsaturated fatty acid salt and the sodium formate in the invention have functions with different purposes, as described above. Therefore, rather than using a linear unsaturated fatty acid salt alone, it is preferable to use a linear unsaturated fatty acid salt and sodium formate in combination. For example, as to be described in Comparative Examples below, in some cases of a resin composition having no linear unsaturated fatty acid salt or sodium formate added, as compared to hole position accuracy before a thermal deterioration acceleration test at 50° C. for one hour, it is observed that hole position accuracy deteriorates after the thermal deterioration acceleration test at 50° C. for one hour. On the contrary, as to be shown in Examples below, in some cases of a resin composition containing a water-soluble resin, a water-soluble lubricant, a linear unsaturated fatty acid salt and sodium formate, it is observed that hole position accuracy is good before a thermal deterioration acceleration test at 50° C. for one hour under air atmosphere, and hole position accuracy further improves after the thermal deterioration acceleration test. Such a fact has not conventionally been known. The inventors think that since in the water-soluble resin composition, the crystal structure is a three dimensional structure, a structure where spherocrystals are crowded in the face direction (XY direction), and a spherocrystal layer is formed in a layer state in the depth direction (Z direction), and not all macromolecules spherocrystallize and an amorphous part exists, a water-soluble linear unsaturated fatty acid salt has a function of making the standard deviation σ of the surface hardness of the resin composition layer further smaller, by dispersing throughout the three dimensional structure, contributing to formation of a spherocrystal in an amorphous part, and forming a fine spherocrystal.

It should be noted that a linear unsaturated fatty acid salt, which is normally water-soluble and washable with water even if remained on a hole wall after drilling, is preferable.

As a method for adding a linear unsaturated fatty acid salt, an optional method can be selected. A linear unsaturated fatty acid salt may be dissolved in water or a solvent in advance and then added to the water-soluble resin composition, or may be added to the water-soluble resin composition directly. A method of dissolving a linear unsaturated fatty acid salt in water or a solvent in advance and then adding it to the water-soluble resin composition makes uniform dispersion easy.

Moreover, when a solvent is used in a preparation step of the water-soluble resin composition, as the solvent, not only water but also a mixed solvent having water and alcohol such as methyl alcohol, ethyl alcohol and isopropyl alcohol mixed may be used. The use of the solvent has a function effect of reducing bubbles remaining in the water-soluble resin composition. On the other hand, a linear unsaturated fatty acid salt has a function effect of making hole position accuracy excellent, by increasing the degree of crystallinity of a water-soluble resin composition, and making the standard deviation σ of the surface hardness of a water-soluble resin composition layer after a thermal deterioration acceleration test small. As the above solvent, using a mixed solvent of water and ethyl alcohol, or a mixed solvent of water and methyl alcohol, which makes hole position accuracy excellent together with the above function effect of a linear unsaturated fatty acid salt, is preferable. Between these two mixed solvents, a mixed solvent of water and methyl alcohol is more preferable in terms of the effect.

While methods for measuring the degree of crystallinity include an X-ray diffraction, a DSC (differential scanning calorimetry) and the like, the degree of crystallinity is defined as a relative value using a DSC in the invention.

Firstly, a DSC (DSC6220 manufactured by SII Nano technology Inc.) is used, the temperature is risen from 30° C. to 100° C., held at 100° C. for three minutes, then cooled from 100° C. to 30° C., held at 30° C. for three minutes, and the temperature rising rate then is +3° C./min and the cooling rate is −3° C./min. This cycle is conducted twice, and the solidifying calorie in the second temperature fall is calculated. The peak in the second solidification is used, since the solidifying temperature does not vary as compared to the first time, and the solidifying temperature of the composition itself can be obtained. 10 mg of water-soluble resin composition sample is used for measurement, and the solidifying calorie per 1 mg of sample is calculated from the obtained data as the solidifying calorie of a soluble resin composition sample.

Secondly, in the invention, a standard resin composition (A) is 100 parts by weight of polyethylene oxide with a weight average molecular weight (Mw) of 110,000 (ALKOX L11 manufactured by Meisei Chemical Works, Ltd.) having 5 parts by weight of 2,7-naphthalene disulfonic acid,3-hydroxy-4-[(4-sulfo-1-naphthalene)azo]-,trisodium salt (Red No. 2) added thereto. The degree of crystallinity of the standard resin composition (A) is defined as 1.0, by using a DSC and calculating the solidifying calorie in the second temperature fall as the solidifying calorie of the standard resin composition (A).

Thirdly, in the invention, the degree of crystallinity of each sample is calculated in the following procedure. For example, in the cases of Examples and Comparative Examples, the above DSC analysis is conducted to calculate the solidifying calorie in the second temperature fall. Then, the degree of crystallinity of a sample is calculated from the following formula.

Degree of crystallinity of sample=solidifying calorie of sample÷solidifying calorie of standard resin composition (A)

In the invention, the solidifying temperature of a water-soluble resin composition is obtained by a DSC measurement similarly to the above. Under the same measurement condition as the above degree of crystallinity measurement, the peak top temperature of the exotherminc peak upon solidification in the second temperature fall is used as the solidifying temperature.

The inventors think that the state of a layer of water-soluble resin composition influencing the performance of an entry sheet is decided when a layer of water-soluble resin composition formed on a metallic support foil surface is cooled from a fused state to solidify. Therefore, rather than a fusing temperature or a fusing calorie while the temperature is rising, it is required to pay attention to a solidifying temperature and a solidifying calorie while the temperature is falling, as described above. Specifically, the higher the solidifying temperature of a water-soluble resin composition is, the higher the degree of crystallinity is, and the more thermally stable it is. As a result, the crystal state of a water-soluble resin composition of an entry sheet for drilling use becomes difficult to be influenced by a thermal history of transport and/or storage environment, and hole position accuracy improves. For example, adding a linear unsaturated fatty acid salt, or a linear unsaturated fatty acid salt and sodium formate to the water-soluble resin composition, as compared to the case of not adding them, since the solidifying temperature is easily increased, improves the degree of crystallinity, and as a result, can make hole position accuracy an excellent value. Particularly, it can make hole position accuracy an excellent value after a thermal deterioration acceleration test, for example a thermal deterioration acceleration test under air atmosphere. Although it depends on the resin composition, as compared to adding a linear unsaturated fatty acid salt alone, adding a linear unsaturated fatty acid salt and sodium formate, which more easily increases the solidifying temperature, is preferable. Thus, the solidifying temperature of a water-soluble resin composition is preferably not less than 30° C., more preferably not less than 35° C., further preferably not less than 40° C., even more preferably not less than 42° C., even further more preferably not less than 44° C., particularly preferably not less than 46° C. On the other hand, the higher the solidifying temperature of a water-soluble resin composition is, the more the lubricant performance as an entry sheet for drilling use is lost. Therefore, the solidifying temperature of a water-soluble resin composition is preferably not more than 70° C., more preferably not more than 65° C., even more preferably not more than 60° C.

An entry sheet for drilling use for a laminated board or a multi-layered board, having a layer of water-soluble resin composition formed on at least one surface of a metallic support foil, wherein the degree of crystallinity of the water-soluble resin composition is not less than 1.2 has not yet been disclosed. The inventors found that a high value of degree of crystallinity contributes to improve hole position accuracy, as described above. For example, adding a linear unsaturated fatty acid salt, or a linear unsaturated fatty acid salt and sodium formate to the water-soluble resin composition, as compared to the case of not adding them, increases the degree of crystallinity, and as a result, can make hole position accuracy an excellent value. Particularly, a linear unsaturated fatty acid salt, which has a different function from sodium formate as described above, has a merit capable of making hole position accuracy an excellent value after a thermal deterioration acceleration test, for example a thermal deterioration acceleration test at 50° C. for one hour under air atmosphere. Thus, the degree of crystallinity of a water-soluble resin composition is not less than 1.2, preferably not less than 1.25, more preferably not less than 1.3, further preferably not less than 1.35, even more preferably not less than 1.4.

Also, the inventors found that a value of the surface hardness of a water-soluble resin composition layer influences hole position accuracy in drilling. Specifically, variability in the surface hardness of a water-soluble resin composition layer is important, and it is necessary to control the surface hardness to be uniform. More specifically, it is necessary to make the standard deviation σ of surface hardness small. For example, adding a linear unsaturated fatty acid salt, or a linear unsaturated fatty acid salt and sodium formate to the water-soluble resin composition, as compared to the case of not adding them, improves the degree of crystallinity and can make variability in surface hardness small. Particularly, it can make variability in surface hardness small after a thermal deterioration acceleration test, for example a thermal deterioration acceleration test under air atmosphere. As a result, it is thought that hole position accuracy can be made as an excellent value. As a method for measuring the surface hardness of a water-soluble resin composition layer, the surface hardness (Martens hardness) of a water-soluble resin composition layer is measured at optional 10 points, from vertically above an entry sheet for drilling use, using a dynamic ultra-micro hardness tester (DUH-211, manufactured by Shimadzu Corporation), under conditions of penetrator: Triangular 115, sample force: 10 mN, loading rate: 0.7316 mN/sec, load holding time: 10 sec, Poisson ratio: 0.07. The average value and the standard deviation σ of the surface hardness obtained then are calculated.

The standard deviation σ of the surface hardness of a water-soluble resin composition layer needs to be not more than 2. When the standard deviation σ is more than 2, hole position accuracy varies due to large variability in surface hardness, which is not preferable. Therefore, the standard deviation σ of the surface hardness of a water-soluble resin composition layer is not more than 2, preferably not more than 1.0, most preferably not more than 0.5.

Also, with the surface hardness of a water-soluble resin composition layer of smaller than 8.5 N/mm², when a drill bit contacts an entry sheet for drilling use, the drilling position is unstable, and hole position accuracy deterioration is liable to occur. Therefore, the surface hardness value of a water-soluble resin composition layer is not less than 8.5 N/mm², preferably not less than 9 N/mm², more preferably not less than 9.5 N/mm², even more preferably not less than 10 N/mm². On the other hand, with the surface hardness of a water-soluble resin composition layer of larger than 25 N/mm², a concern of drill bit breakage increases. Therefore, the surface hardness of a water-soluble resin composition layer is not more than 25 N/mm², preferably not more than 20 N/mm².

Thermal stability of the entry sheet for drilling use of the invention can be confirmed with the hole position accuracy change ratio (%) and the standard deviation σ of surface hardness (N/mm²) before and after a thermal deterioration acceleration test. The thermal deterioration acceleration test refers to a test of being left at a higher temperature than ambient temperature for a given time under air atmosphere, as described above. Specifically, an explosion proof type dryer (SPHH-202, manufactured by ESPEC Corporation) is used, under open atmospheric system (air atmosphere), an entry sheet for drilling use having been cut into a 50×100 mm size is placed flat with a water-soluble resin composition layer as an upper layer (a metallic support foil as a lower layer), for example left at 50° C. for one hour, and then left under room temperature (25° C.) atmosphere. It should be noted that the thermal deterioration acceleration test temperature is set accordingly as higher than the solidifying temperature of a water-soluble resin composition, lower than the melting point. With a temperature higher than the melting point, a water-soluble resin composition melts, properties it had until it melted becomes unclear, and property evaluation as an entry sheet for drilling use cannot be conducted. On the other hand, with a temperature lower than the solidifying temperature, it is not an acceleration test for examining thermal stability.

The hole position accuracy of an entry sheet for drilling use varies with influences of a material to be drilled, drilling conditions, a drill bit diameter and the like. Therefore, rather than simply comparing hole position accuracy values, in order to conduct a relative comparison, a method of comparing the change ratio (%) of hole position accuracy before and after a thermal deterioration acceleration test, for example, a thermal deterioration acceleration test at 50° C. for one hour under air atmosphere can be adopted. Here, the change ratio of hole position accuracy can be calculated from the following formula.

Change ratio (%) of hole position accuracy=(hole position accuracy after a thermal deterioration acceleration test−hole position accuracy before a thermal deterioration acceleration test)÷hole position accuracy before a thermal deterioration acceleration test×100

In the invention, the change ratio (%) of hole position accuracy before and after a thermal deterioration acceleration test, for example, a thermal deterioration acceleration test at 50° C. for one hour under air atmosphere is preferable to be within +10%. This means that when hole position accuracy becomes smaller (hole position accuracy improves) after a thermal deterioration acceleration test, a value becomes minus, while when hole position accuracy becomes larger (hole position accuracy deteriorates), a value becomes plus, and the larger the minus value is, the more excellent the performance of thermal deterioration prevention is. Therefore, the change ratio of hole position accuracy before and after a thermal deterioration acceleration test is preferably within +10%, more preferably within +5%, further preferably 0%, further more preferably within −5%. Also, needless to say, even if a value of the above hole position accuracy change ratio (%) looks to be an excellent value, the purpose is not accomplished when hole position accuracy (μm) as the absolute value is not excellent.

Originally, regarding the hole position accuracy property required for an entry sheet for drilling use, a standard value varies depending on a drill bit diameter or a material to be drilled. For example, when the evaluation condition is that a drill bit diameter is 0.2 mmφ in Examples of the subject application, the standard value is about 20 μm as an average value of Ave.+3σ. For example, in that regard, when the value of hole position accuracy the sheet originally has is 18 μm, after the sheet is exposed to a high temperature and hole position accuracy deteriorates, it becomes 19.8 mμ by +10%, 20.7 mμ by +15%, 21.6 mμ by +20%, which exceed the standard value. Therefore, an entry sheet for drilling use needs to be stable against ambient temperature, the deterioration ratio of hole position accuracy is preferably within +10%, and it is preferable to maintain hole position accuracy at a designed value.

As a method for preparing a water-soluble resin composition, a method of dissolving a single or a plurality of water-soluble resin components in a solvent and then adding a linear unsaturated fatty acid salt, or a linear unsaturated fatty acid salt and sodium formate to the solution to form a solution of water-soluble resin composition, a method of melting a single or a plurality of water-soluble resin components and then further adding a linear unsaturated fatty acid salt, or a linear unsaturated fatty acid salt and sodium formate to form a hot melt of water-soluble resin composition, and the like are illustrated.

In the invention, methods of forming a water-soluble resin composition layer include, for example, a method of accordingly melting a water-soluble resin composition, or dissolving or dispersing it in a solvent into a liquid state, coating it on at least one surface of a metallic support foil, and drying it to form a water-soluble resin composition layer, a method of forming a water-soluble resin composition layer in advance, then superimposing the water-soluble resin composition layer on at least one surface of a metallic support foil, bonding it by heating with a roll etc. or with an adhesive etc., and the like. The method for producing a water-soluble resin composition layer is not particularly limited, as long as it is a publicly known method for industry use. Specifically, a method of mixing a water-soluble resin composition using a roll, a kneader, or other kneading means and accordingly melting, and forming a water-soluble resin composition layer on a release film by a rolling method, a curtain coating method, etc., a method of forming a water-soluble resin composition into a water-soluble resin composition sheet with a desirable thickness in advance using a roll, a T-die extruder etc., and the like are exemplified. Moreover, having a resin membrane formed in advance on the front layer of a metallic support foil where a water-soluble resin composition layer is to be formed is convenient for laminating and integrating a metallic support foil and a water-soluble resin composition layer.

Also, the condition for coating a solution of water-soluble resin composition directly on a metallic support foil and then drying the water-soluble resin composition solution is desirable to be optimized, depending on the thickness of a water-soluble resin composition layer. Specifically, it is dried preferably at a temperature of 120° C. to 160° C. for a holding time of 10 seconds to 600 seconds, further preferably at a temperature of 120° C. to 160° C. for a holding time of 10 seconds to 500 seconds, even more preferably at a temperature of 120° C. to 160° C. for a holding time of 15 seconds to 400 seconds, particularly preferably at a temperature of 120° C. to 150° C. for a holding time of 20 seconds to 300 seconds. When the drying temperature is less than 120° C., or the holding time at the drying temperature is less than 10 seconds, a solvent may remain the inside of a water-soluble resin composition layer, or since the calorie required for fusing a water-soluble resin composition lacks, a water-soluble resin composition layer may not be formed uniformly. On the other hand, when the drying temperature is as high as more than 200° C., or the holding time is more than 600 seconds, decomposition of a water-soluble resin composition may occur, and a problem may occur in appearance.

The cooling condition for a water-soluble resin composition of an entry sheet for drilling use is generally a cooling rate of less than 1.2° C./sec. While the cooling condition for the water-soluble resin composition in the invention may be a cooling rate of less than 1.2° C./sec, it is preferable to cool it from a cooling start temperature of 120° C. to 160° C. to a cooling end temperature of 25° C. to 40° C. within 60 seconds at a cooling rate of not less than 1.5° C./sec. Of course, the cooling end temperature needs to be set as lower than the solidifying temperature of a water-soluble resin composition. However, when the cooling end temperature is lower than 15° C., warpage may occur in the entry sheet, and also dew condensation may be caused in the post process, which is not preferable. When the cooling rate is less than 1.5° C./sec, the cooling time is liable to be long and more than 60 seconds, which is not preferable. Therefore, as the cooling condition, it is cooled preferably from a temperature of 120° C. to 160° C. to a temperature of 25° C. to 40° C. within 50 seconds at a cooling rate of not less than 2° C./sec, more preferably from a temperature of 120° C. to 160° C. to a temperature of 25° C. to 40° C. within 40 seconds at a cooling rate of not less than 2.5° C./sec, more preferably from a temperature of 120° C. to 160° C. to a temperature of 25° C. to 40° C. within 30 seconds at a cooling rate of not less than 3° C./sec, further preferably from a temperature of 120° C. to 160° C. to a temperature of 25° C. to 40° C. within 20 seconds at a cooling rate of not less than 4.5° C./sec, most preferably from a temperature of 120° C. to 160° C. to a temperature of 25° C. to 40° C. within 15 seconds at a cooling rate of not less than 6° C./sec.

As a metal species of a metallic support foil for use in the entry sheet for drilling use of the invention, aluminum is preferable, and the thickness of a metallic support foil is normally 0.05 to 0.5 mm, preferably 0.05 to 0.3 mm. When the thickness of a metallic support foil is less than 0.05 mm, a burr of a laminated board is easily generated during drilling, while when it is more than 0.5 mm, discharge of chips generated during drilling becomes difficult. Also, as a material for an aluminum foil, aluminum with a purity of not less than 95% is preferable, and specifically, 5052, 3004, 3003, 1N30, 1N99, 1050, 1070, 1085, 8021 and the like specified in JIS-H4160 are exemplified. Using an aluminum foil with a high purity for a metallic support foil improves impact relaxation and biting property of a drill bit, and improves hole position accuracy of a drilled hole together with an effect of lubricating a drill bit by a water-soluble resin composition. Moreover, using these aluminum foils having a resin membrane with a thickness of 0.001 to 0.02 mm formed in advance thereon is preferable in terms of adhesion to a water-soluble resin composition. The thickness of a resin membrane is more preferable to be 0.001 to 0.01 mm. A resin used in a resin membrane is not particularly limited, and may be either a thermoplastic resin or a thermosetting resin. For example, as a thermoplastic resin, an urethane based polymer, a vinyl acetate based polymer, a vinyl chloride based polymer, a polyester based polymer, and a copolymer thereof are exemplified. As a thermosetting resin, a resin such as an epoxy based resin and a cyanate based resin are exemplified. Furthermore, as a metallic support foil used in the invention, a commercially available metallic foil having a resin membrane coated in advance thereon by a publicly known method may be used.

In addition, the function effect of a linear unsaturated fatty acid salt is to improve hole position accuracy into an excellent value, by adding it to a water-soluble resin composition, improving the degree of crystallinity, and making variability in surface hardness small, as describe above. Therefore, adding it to the above resin membrane does not exhibit an expected function effect.

The entry sheet for drilling use of the invention is considered to be used in drilling with a drill bit diameter of not less than 0.05 mmφ to not more than 0.3 mmφ, in drilling a laminated board or a multi-layered board. Particularly, it is preferred for a small diameter application of not less than 0.05 mmφ to not more than 0.15 mmφ, more particularly for an ultra-small diameter application of not less than 0.05 mmφ to not more than 0.105 mmφ, wherein hole position accuracy is important.

Although the thickness of a water-soluble resin composition layer in the entry sheet for drilling use of the invention varies depending on a drill bit diameter used in drilling, the structure of a laminated board or a multi-layered board and the like, it is normally within a range of 0.01 to 0.3 mm, preferably within a range of 0.02 to 0.2 mm, further preferably within a range of 0.02 to 0.12 mm. When the thickness of a water-soluble resin composition layer is less than 0.01 mm, a sufficient lubricant effect cannot be obtained, hole wall roughness deteriorates, and also a drill bit breaks due to large load on a drill bit. On the other hand, when the thickness of a water-soluble resin composition layer is more than 0.3 mm, resins twining around a drill bit may increase.

The thickness of each layer consisting an entry sheet for drilling use is measured as follows. An entry sheet for drilling use is cut from the water-soluble resin composition layer surface of an entry sheet for drilling use in the vertical direction to the water-soluble resin composition layer with a Cross Section Polisher (SM-09010 manufactured by JOEL Ltd.), or an Ultramicrotome (EM UC7 manufactured by Leica Microsystems GmbH), then the cross section is observed in the vertical direction to the cross section with an SEM (Scanning Electron Microscope VE-7800 manufactured by Keyence Corporation), and the thickness of an aluminum layer and a water-soluble resin composition layer is measured in a field of 900 times power. The thickness of 5 positions per field is measured and the average is calculated as the thickness of each layer.

Drilling with the entry sheet for drilling use of the invention is conducted in drilling a printed wiring board, for example a laminated board or a multi-layered board, by superimposing one or a plurality of laminated boards or multi-layered boards, disposing on at least the top thereof the entry sheet with the metallic support foil side in contact with a printed wiring board material, and drilling from the surface of a water-soluble resin composition layer of the entry sheet for drilling use.

### EXAMPLES

The invention will be specifically described by showing Examples and Comparative Examples below. It should be noted that the following examples have merely shown one example of the embodiments of the invention, rather than limiting the invention. Also in Examples, “polyethylene glycol” may be abbreviated as “PEG”, “polyethylene oxide” as “PEO”, “polyether ester” as “PEE”, “methyl alcohol” as “MeOH”, and “ethyl alcohol” as “EtOH”.

In Table 1, the raw material specification of resins, thermal stabilizers and the like used in producing entry sheets for drilling use in Examples and Comparative Examples is shown. It should be noted that a thermal stabilizer in the invention is an additive exhibiting a function effect of reducing thermal deterioration of hole position accuracy of an entry sheet for drilling use, or thermally improving hole position accuracy of an entry sheet for drilling use. Specifically, it is an additive exhibiting the above function effect, under given drilling conditions to be described below, after a thermal deterioration acceleration test of being exposed to air atmosphere. Thermal stabilizers include not only linear unsaturated fatty acid salts used in the invention (sodium sorbate, sodium oleate, potassium oleate, sodium linoleate), but also 2,7-naphthalendisulfonic acid,3-hydroroxy-4-[(4-sulfo-1-naphthalene)azo]-,trisodium salt (Red No. 2) used in a standard sample.

TABLE 1

| Classification | | Name or Condition | Trade Name | Manufacturer | Remarks |
|---|---|---|---|---|---|
| Resin | PEO | Polyethylene Oxide | ALKOX L11 | Meisei Chemical Works, Ltd. | Mw = 110,000 |
| | PEG | Polyethylene Glycol | PEG20000 | Sanyo Chemical Industries, Ltd. | Mw = 20,000 |
| | PEE | Polyether Ester | PAOGEN PP-15 | Dai-ichi Kogyo Seiyaku, Co., Ltd. | Mw = 100,000 |
| Thermal | (a) | Sodium Sorbate | — | Tokyo Chemical Industry Co., Ltd. | Linear Unsaturated Fatty |
| | | | | | Acid Salt |
| Stabilizer | (b) | Sodium Oleate | — | Kanto Chemical Co., Inc. | Linear Unsaturated Fatty |
| | | | | | Acid Salt |
| | (c) | Potassium Oleate | — | Tokyo Chemical Industry Co., Ltd. | Linear Unsaturated Fatty |
| | | | | | Acid Salt |
| | (d) | Sodium Linoleate | — | Tokyo Chemical Industry Co., Ltd. | Linear Unsaturated Fatty |
| | | | | | Acid Salt |
| | (n) | Red No. 2 | Amaranth | Kanto Chemical Co., Inc. | — |
| Additive | (e) | Sodium Hexanoate | — | Tokyo Chemical Industry Co., Ltd. | Linear Unsaturated Fatty |
| | | | | | Acid Salt |
| | (f) | Sodium Stearate | — | Kanto Chemical Co., Inc. | Linear Unsaturated Fatty |
| | | | | | Acid Salt |
| | (g) | Calcium Stearate | — | Kanto Chemical Co., Inc. | Linear Unsaturated Fatty |
| | | | | | Acid Salt |
| | (h) | Sodium L-glutamate | — | Kanto Chemical Co., Inc. | Other Organic Acid Salt |
| | (i) | Calcium Formate | — | Kanto Chemical Co., Inc. | Other Organic Acid Salt |
| | (j) | Sodium Benzoate | — | Kanto Chemical Co., Inc. | Other Organic Acid Salt |
| | (k) | Calcium Acetate Monohydride | — | Kanto Chemical Co., Inc. | Other Organic Acid Salt |
| | (l) | Sodium Carbonate Monohydride | — | Kanto Chemical Co., Inc. | Other Organic Acid Salt |
| | (m) | Hydroquinone | — | Kanto Chemical Co., Inc. | Antioxidant |

| | | | | |
|---|---|---|---|---|
| Nucleating Agent | Sodium Formate | — | Mitsubishi Gas Chemical Company, Inc. | — |
| Solvent | Methyl Alcohol | — | Mitsubishi Gas Chemical Company, Inc. | — |
| | Ethyl Alcohol | — | Wako Pure Chemical Industries, Ltd. | — |
| Drill Bit | — | CFU020S | Tungaloy Corporation | 0.2 mmφ |
| Aluminum Foil | — | 0.1 mmt | Mitsubishi Aluminum Co., Ltd. | JIS Standard 1100 |
| | — | 0.07 mmt | Mitsubishi Aluminum Co., Ltd. | JIS Standard 1100 |

### Example 1

80 parts by weight of polyethylene oxide with a weight average molecular weight of 110,000 (ALKOX L11, manufactured by Meisei Chemical Works, Ltd.) and 20 parts by weight of polyethylene glycol with a weight average molecular weight of 20,000 (PEG20000, manufactured by Sanyo Chemical Industries, Ltd.) were fully dissolved in a mixed solvent of water and MeOH so that the resin solid content was 30%. The ratio of water to MeOH then was 70 parts by weight to 30 parts by weight.

Further, 0.1 parts by weight of sodium oleate (manufactured by Kanto Chemical Co., Inc.) based on 100 parts by weight of the solid content of this water-soluble resin composition was added and fully dissolved. A solution of this water-soluble resin composition was coated on an aluminum foil (JIS standard 1100, thickness 0.1 mm, manufactured by Mitsubishi Aluminum Co, Ltd.) having an epoxy resin membrane with a thickness of 0.01 mm formed on one surface using a bar coater so that a water-soluble resin composition layer after drying was 0.05 mm, dried with a dryer at 120° C. for five minutes, and further cooled at a cooling rate of 3.1° C./sec to produce an entry sheet for drilling use. In addition, a cooling start temperature was 120° C., a cooling end temperature was 27° C., and it was cooled from the cooling start temperature to the cooling end temperature in 30 seconds at a cooling rate of 3.1° C./sec.

The obtained entry sheet for drilling use was disposed on the top of five superimposed copper clad laminated boards with a thickness of 0.2 mm (CCL-HL832, copper foil both surfaces 12 μm, manufactured by Mitsubishi Gas Chemical Company, Inc.) with a water-soluble resin composition layer facing up, a reinforcing board (bakelite board) was disposed on the downside of the superimposed copper clad laminated boards, and drilling was conducted with four drill bits, by 3,000 hits per drill bit, under conditions of drill bit: 0.2 mmφ (CFU020S, manufactured by Tungaloy Corporation), rotation rate: 200,000 rpm, and feed rate: 2.6 m/min.

Next, an explosion proof type dryer (SPHH-202, manufactured by ESPEC Corporation) was used, under open atmospheric system (air atmosphere), the above entry sheet for drilling use which was unused and have been cut into a 50×100 mm size was placed flat with a water-soluble resin composition layer as an upper layer (a metallic support foil as a lower layer), left at 50° C. for one hour, and then left under room temperature (25° C.) atmosphere. Then, this entry sheet for drilling use was disposed on the top of five superimposed copper clad laminated boards with a thickness of 0.2 mm (CCL-HL832, copper foil both surfaces 12 manufactured by Mitsubishi Gas Chemical Company, Inc.) with a water-soluble resin composition layer facing up, a reinforcing board (bakelite board) was disposed on the downside of the superimposed copper clad laminated boards, and drilling was conducted with four drill bits, by 3,000 hits per drill bit, under conditions of drill bit: 0.2 mmφ(CFU020S, manufactured by Tungaloy Corporation), rotation rate: 200,000 rpm, and feed rate: 2.6 m/min.

### Examples 3 to 13, 15, 17 to 35, Comparative Examples 1, 3 to 9, 11 to 49

For Examples 3 to 13, 15, 17 to 35 and Comparative Examples 1, 3 to 9, 11 to 49, according to Example 1, a water-soluble resin composition shown in Table 2 was prepared, a solution of this water-soluble resin composition was coated on an aluminum foil (JIS standard 1100, thickness 0.1 mm, manufactured by Mitsubishi Aluminum Co, Ltd.) having an epoxy resin membrane with a thickness of 0.01 mm formed on one surface using a bar coater so that a water-soluble resin composition layer after drying was 0.05 mm, and dried with a dryer at 120° C. for five minutes. Further, for Examples 3 to 12, 15, 17 to 35 and Comparative Examples 3, 5 to 7, 9, 11 to 49, it was cooled at a cooling rate of 3.1° C./sec to produce an entry sheet for drilling use. For Example 13, it was cooled after coating and drying at a cooling rate of 2.0° C./sec to produce an entry sheet for drilling use. The cooling start temperature was 120° C., the cooling end temperature was 27° C., and it was cooled from the cooling start temperature to the cooling end temperature in 46.5 seconds at a cooling rate of 2.0° C./sec to produce an entry sheet for drilling use. Also, for Comparative Examples 1, 4, 8, it was cooled after coating and drying at a cooling rate of 1.0° C./sec to produce an entry sheet for drilling use. The cooling start temperature was 120° C., the cooling end temperature was 27° C., and it was cooled from the cooling start temperature to the cooling end temperature in 93 seconds at a cooling rate of 1.0° C./sec to produce an entry sheet for drilling use.

Next, by using this entry sheet for drilling use, drilling was conducted according to Example 1.

Also, according to Example 1, by using an explosion proof type dryer (SPHH-202 manufactured by ESPEC Corporation), it was left under each condition of temperature and time, and then left under room temperature (25° C.) atmosphere to produce an entry sheet for drilling use after a thermal deterioration acceleration test, and drilling was conducted.

### Examples 2, 14, 16, Comparative Examples 2, 10

For Examples 2, 14, 16 and Comparative Examples 2, 10, according to Example 1, a water-soluble resin composition shown in Table 2 was prepared, a solution of this water-soluble resin composition was coated on an aluminum foil (JIS standard 1100, thickness 0.1 mm, manufactured by Mitsubishi Aluminum Co, Ltd.) having an epoxy resin membrane with a thickness of 0.01 mm formed on one surface using a bar coater so that a water-soluble resin composition layer after drying was 0.03 mm, dried with a dryer at 120° C. for three minutes, and further cooled under a cooling condition according to Example 1 to produce an entry sheet for drilling use.

The obtained entry sheet for drilling use was disposed on the top of six superimposed copper clad laminated boards with a thickness of 0.1 mm (CCL-HL832NXA, copper foil both surfaces 3 μm, manufactured by Mitsubishi Gas Chemical Company, Inc.) with a water-soluble resin composition layer facing up, a reinforcing board (bakelite board) was disposed on the downside of the superimposed copper clad laminated boards, and drilling was conducted with four drill bits, by 3,000 hits per drill bit, under conditions of drill bit: 0.105 mmφ (MD 1492B 0.105×1.6, manufactured by Union Tool Co.), rotation rate: 200,000 rpm, and feed rate: 1.6 m/min.

Also, according to Example 1, by using an explosion proof type dryer (SPHH-202 manufactured by ESPEC Corporation), it was left under each condition of temperature and time, and then left under room temperature (25° C.) atmosphere to produce an entry sheet for drilling use after a thermal deterioration acceleration test, and drilling was conducted.

Table 3 shows hole position accuracy Ave.+3σ (μm), hole position accuracy change amount Δ Ave.+3σ (μm), hole position accuracy change ratio Ave.+3σ (%), solidifying temperature (° C.), solidifying calorie (J/mg), degree of crystallinity, surface hardness Ave. (N/mm²), standard deviation σ of surface hardness (N/mm²), and comprehensive judgment of Examples 1 to 35 and Comparative Examples 1 to 49. These evaluation methods will be described below.

<Standard Sample 1>

Polyethylene oxide with a weight average molecular weight of 110,000 (ALKOX L11, manufactured by Meisei Chemical Works, Ltd.) was fully dissolved in a mixed solution of water and MeOH so that the resin solid content was 30%. The ratio of water to MeOH then was 70 parts by weight to 30 parts by weight. A solution of water-soluble resin composition having 5 parts by weight of Red No. 2 based on 100 parts by weight of polyethylene oxide added was coated on an aluminum foil (JIS standard 1100, thickness 0.1 mm, manufactured by Mitsubishi Aluminum Co, Ltd.) having an epoxy resin membrane with a thickness of 0.01 mm formed on one surface using a bar coater so that the thickness of a water-soluble resin composition layer after drying was 0.05 mm, dried with a dryer at 120° C. for five minutes, and further cooled at a cooling rate of 1.0° C./sec to produce an entry sheet for drilling use. This was used as a standard sample for measurement of the degree of crystallinity.

<Standard Samples 2, 3, 5>

Polyethylene oxide with a weight average molecular weight of 110,000 (ALKOX L11, manufactured by Meisei Chemical Works, Ltd.) was fully dissolved in a mixed solution of water and MeOH so that the resin solid content was 30%. The ratio of water to MeOH then was 70 parts by weight to 30 parts by weight. A solution of water-soluble resin composition having 5 parts by weight of Red No. 2 based on 100 parts by weight of polyethylene oxide added was coated on an aluminum foil (JIS standard 1100, thickness 0.1 mm, manufactured by Mitsubishi Aluminum Co, Ltd.) having an epoxy resin membrane with a thickness of 0.01 mm formed on one surface using a bar coater so that the thickness of a water-soluble resin composition layer after drying was 0.05 mm, dried with a dryer at 120° C. for five minutes, and further cooled at a cooling rate of 3.1° C./sec to produce an entry sheet for drilling use. In addition, this cooling condition was the same as Example 1. This was used as a standard sample for measurement of the degree of crystallinity. It should be noted that the experiment day was different for Standard Samples 2, 3, 5. In Examples herein, in order to make data accuracy more excellent, a standard sample was produced on each experiment day.

<Standard Sample 4>

According to Standard Samples 1 to 3, 5, a water-soluble resin composition was prepared, and a solution of this water-soluble resin composition was coated on an aluminum foil (JIS standard 1100, thickness 0.7 mm, manufactured by Mitsubishi Aluminum Co, Ltd.) having an epoxy resin membrane with a thickness of 0.01 mm formed on one surface using a bar coater so that the thickness of a water-soluble resin composition layer after drying was 0.03 mm, dried with a dryer at 120° C. for three minutes, and further cooled at a cooling rate of 3.1° C./sec to produce an entry sheet for drilling use. In addition, this cooling condition was the same as Example 1. This was used as a standard sample for measurement of the degree of crystallinity.

Next, an explosion proof type dryer (SPHH-202 manufactured by ESPEC Corporation) was used, under open atmospheric system (air atmosphere), the above Standard Samples 1 to 5 for measurement of the degree of crystallinity which was unused and have been cut into a 50×100 mm size was placed flat with a water-soluble resin composition layer as an upper layer (a metallic support foil as a lower layer), left at 50° C. for one hour, and then left under room temperature (25° C.) atmosphere. This was used as a standard sample for measurement of the degree of crystallinity after a thermal deterioration acceleration test.

A standard sample used in measurement of the degree of crystallinity of each of Examples and Comparative Examples was accordingly selected from the above Standard Samples 1 to 5 considering the experiment day and the cooling condition etc. of the standard sample.

TABLE 2

| | | | | | Nucleating | | | | | | |
|---|---|---|---|---|---|---|---|---|---|---|---|
| | | | Thermal | | Agent | | | | | | |
| | | | Stabilizer | | Sodium | | | | | | |
| | Resin | | etc. | | Formate | | | | | | |
| | | Contained | | Added | Added | Solvent | | | | Drill Bit | |
| | | Amount | | Amount | Amount | Water:Alcohol | | Cooling | Thermal | Dia- | |
| | | Parts by | | Parts by | Parts by | Weight | Alcohol | Rate | Treatment | meter | Standard |
| Classification | Composition | Weight | Name | Weight | Weight | Ratio | Name | ° C./sec | Condition | mmφ | Sample |
| Example 1 | A | 100 | b | 0.1 | 0 | 7:3 | MeOH | 3.1 | F | 0.2 | 2 |
| Example 2 | A | 100 | b | 10 | 0 | 7:3 | MeOH | 3.1 | F | 0.105 | 4 |
| Example 3 | A | 100 | b | 10 | 0 | 7:3 | MeOH | 3.1 | F | 0.2 | 2 |
| Example 4 | B | 100 | b | 0.1 | 0.25 | 7:3 | MeOH | 3.1 | F | 0.2 | 2 |
| Example 5 | B | 100 | b | 0.25 | 0.25 | 7:3 | MeOH | 3.1 | F | 0.2 | 2 |
| Example 6 | B | 100 | b | 1 | 0 | 7:3 | EtOH | 3.1 | F | 0.2 | 3 |
| Example 7 | B | 100 | b | 1 | 0 | 6:4 | MeOH | 3.1 | F | 0.2 | 3 |
| Example 8 | B | 100 | b | 1 | 0 | 7:3 | MeOH | 3.1 | F | 0.2 | 3 |
| Example 9 | B | 100 | b | 1 | 0 | 9:1 | MeOH | 3.1 | F | 0.2 | 3 |
| Example 10 | B | 100 | b | 1 | 0.25 | 7:3 | MeOH | 3.1 | F | 0.2 | 2 |
| Example 11 | B | 100 | b | 1 | 1 | 7:3 | MeOH | 3.1 | F | 0.2 | 3 |
| Example 12 | B | 100 | b | 5 | 0.25 | 7:3 | MeOH | 3.1 | F | 0.2 | 2 |
| Example 13 | B | 100 | b | 10 | 0 | 7:3 | MeOH | 2.0 | F | 0.2 | 3 |
| Example 14 | B | 100 | b | 10 | 0 | 7:3 | MeOH | 3.1 | F | 0.105 | 4 |
| Example 15 | B | 100 | b | 10 | 0.25 | 7:3 | MeOH | 3.1 | F | 0.2 | 2 |
| Example 16 | B | 100 | b | 10 | 1 | 7:3 | MeOH | 3.1 | F | 0.105 | 4 |
| Example 17 | B | 100 | b | 10 | 1 | 7:3 | MeOH | 3.1 | F | 0.2 | 3 |
| Example 18 | C | 100 | b | 10 | 0 | 7:3 | MeOH | 3.1 | F | 0.2 | 2 |
| Example 19 | E | 100 | B | 1 | 0 | 7:3 | MeOH | 3.1 | F | 0.2 | 3 |
| Example 20 | B | 100 | a | 0.5 | 0 | 7:3 | MeOH | 3.1 | F | 0.2 | 5 |
| Example 21 | B | 100 | b | 0.5 | 0 | 7:3 | MeOH | 3.1 | F | 0.2 | 5 |
| Example 22 | B | 100 | c | 0.5 | 0 | 7:3 | MeOH | 3.1 | F | 0.2 | 5 |
| Example 23 | B | 100 | d | 0.5 | 0 | 7:3 | MeOH | 3.1 | F | 0.2 | 5 |
| Example 24 | B | 100 | a | 0.5 | 0 | 7:3 | MeOH | 3.1 | G | 0.2 | 5 |
| Example 25 | B | 100 | b | 0.5 | 0 | 7:3 | MeOH | 3.1 | G | 0.2 | 5 |
| Example 26 | B | 100 | c | 0.5 | 0 | 7:3 | MeOH | 3.1 | G | 0.2 | 5 |
| Example 27 | B | 100 | d | 0.5 | 0 | 7:3 | MeOH | 3.1 | G | 0.2 | 5 |
| Example 28 | B | 100 | a | 0.5 | 0 | 7:3 | MeOH | 3.1 | H | 0.2 | 5 |
| Example 29 | B | 100 | b | 0.5 | 0 | 7:3 | MeOH | 3.1 | H | 0.2 | 5 |
| Example 30 | B | 100 | c | 0.5 | 0 | 7:3 | MeOH | 3.1 | H | 0.2 | 5 |
| Example 31 | B | 100 | d | 0.5 | 0 | 7:3 | MeOH | 3.1 | H | 0.2 | 5 |
| Example 32 | B | 100 | a | 0.5 | 0 | 7:3 | MeOH | 3.1 | I | 0.2 | 5 |
| Example 33 | B | 100 | b | 0.5 | 0 | 7:3 | MeOH | 3.1 | I | 0.2 | 5 |
| Example 34 | B | 100 | c | 0.5 | 0 | 7:3 | MeOH | 3.1 | I | 0.2 | 5 |
| Example 35 | B | 100 | d | 0.5 | 0 | 7:3 | MeOH | 3.1 | I | 0.2 | 5 |
| Comparative Example 1 | A | 100 | — | 0 | 0 | 7:3 | MeOH | 1.0 | F | 0.2 | 1 |
| Comparative Example 2 | A | 100 | — | 0 | 0 | 7:3 | MeOH | 3.1 | F | 0.105 | 4 |
| Comparative Example 3 | A | 100 | — | 0 | 0 | 7:3 | MeOH | 3.1 | F | 0.2 | 2 |
| Comparative Example 4 | A | 100 | h | 0.1 | 0 | 7:3 | MeOH | 1.0 | F | 0.2 | 1 |
| Comparative Example 5 | A | 100 | i | 0.1 | 0 | 7:3 | MeOH | 3.1 | F | 0.2 | 2 |
| Comparative Example 6 | A | 100 | g | 0.1 | 0 | 7:3 | MeOH | 3.1 | F | 0.2 | 2 |
| Comparative Example 7 | A | 100 | j | 0.1 | 0 | 7:3 | MeOH | 3.1 | F | 0.2 | 2 |
| Comparative Example 8 | A | 100 | k | 0.1 | 0 | 7:3 | MeOH | 1.0 | F | 0.2 | 1 |
| Comparative Example 9 | A | 100 | l | 0.1 | 0 | 7:3 | MeOH | 3.1 | F | 0.2 | 2 |
| Comparative Example 10 | B | 100 | — | 0 | 0 | 7:3 | MeOH | 3.1 | F | 0.105 | 4 |
| Comparative Example 11 | B | 100 | — | 0 | 0 | 7:3 | MeOH | 3.1 | F | 0.2 | 2 |
| Comparative Example 12 | B | 100 | — | 0 | 0.25 | 7:3 | MeOH | 3.1 | F | 0.2 | 2 |
| Comparative Example 13 | B | 100 | — | 0 | 0.5 | 7:3 | MeOH | 3.1 | F | 0.2 | 2 |
| Comparative Example 14 | B | 100 | — | 0.5 | 0 | 7:3 | MeOH | 3.1 | F | 0.2 | 5 |
| Comparative Example 15 | B | 100 | e | 0.5 | 0 | 7:3 | MeOH | 3.1 | F | 0.2 | 5 |
| Comparative Example 16 | B | 100 | f | 0.5 | 0 | 7:3 | MeOH | 3.1 | F | 0.2 | 5 |
| Comparative Example 17 | B | 100 | g | 0.5 | 0 | 7:3 | MeOH | 3.1 | F | 0.2 | 5 |
| Comparative Example 18 | B | 100 | i | 0.5 | 0 | 7:3 | MeOH | 3.1 | F | 0.2 | 5 |
| Comparative Example 19 | B | 100 | j | 0.5 | 0 | 7:3 | MeOH | 3.1 | F | 0.2 | 5 |
| Comparative Example 20 | B | 100 | k | 0.5 | 0 | 7:3 | MeOH | 3.1 | F | 0.2 | 5 |
| Comparative Example 21 | B | 100 | l | 0.5 | 0 | 7:3 | MeOH | 3.1 | F | 0.2 | 5 |
| Comparative Example 22 | B | 100 | m | 0.5 | 0 | 7:3 | MeOH | 3.1 | F | 0.2 | 5 |
| Comparative Example 23 | B | 100 | — | 0.5 | 0 | 7:3 | MeOH | 3.1 | G | 0.2 | 5 |
| Comparative Example 24 | B | 100 | e | 0.5 | 0 | 7:3 | MeOH | 3.1 | G | 0.2 | 5 |
| Comparative Example 25 | B | 100 | f | 0.5 | 0 | 7:3 | MeOH | 3.1 | G | 0.2 | 5 |
| Comparative Example 26 | B | 100 | g | 0.5 | 0 | 7:3 | MeOH | 3.1 | G | 0.2 | 5 |
| Comparative Example 27 | B | 100 | i | 0.5 | 0 | 7:3 | MeOH | 3.1 | G | 0.2 | 5 |
| Comparative Example 28 | B | 100 | j | 0.5 | 0 | 7:3 | MeOH | 3.1 | G | 0.2 | 5 |
| Comparative Example 29 | B | 100 | k | 0.5 | 0 | 7:3 | MeOH | 3.1 | G | 0.2 | 5 |
| Comparative Example 30 | B | 100 | l | 0.5 | 0 | 7:3 | MeOH | 3.1 | G | 0.2 | 5 |
| Comparative Example 31 | B | 100 | m | 0.5 | 0 | 7:3 | MeOH | 3.1 | G | 0.2 | 5 |
| Comparative Example 32 | B | 100 | — | 0.5 | 0 | 7:3 | MeOH | 3.1 | H | 0.2 | 5 |
| Comparative Example 33 | B | 100 | e | 0.5 | 0 | 7:3 | MeOH | 3.1 | H | 0.2 | 5 |
| Comparative Example 34 | B | 100 | f | 0.5 | 0 | 7:3 | MeOH | 3.1 | H | 0.2 | 5 |
| Comparative Example 35 | B | 100 | g | 0.5 | 0 | 7:3 | MeOH | 3.1 | H | 0.2 | 5 |
| Comparative Example 36 | B | 100 | i | 0.5 | 0 | 7:3 | MeOH | 3.1 | H | 0.2 | 5 |
| Comparative Example 37 | B | 100 | j | 0.5 | 0 | 7:3 | MeOH | 3.1 | H | 0.2 | 5 |
| Comparative Example 38 | B | 100 | k | 0.5 | 0 | 7:3 | MeOH | 3.1 | H | 0.2 | 5 |
| Comparative Example 39 | B | 100 | l | 0.5 | 0 | 7:3 | MeOH | 3.1 | H | 0.2 | 5 |
| Comparative Example 40 | B | 100 | m | 0.5 | 0 | 7:3 | MeOH | 3.1 | H | 0.2 | 5 |
| Comparative Example 41 | B | 100 | — | 0.5 | 0 | 7:3 | MeOH | 3.1 | I | 0.2 | 5 |
| Comparative Example 42 | B | 100 | e | 0.5 | 0 | 7:3 | MeOH | 3.1 | I | 0.2 | 5 |
| Comparative Example 43 | B | 100 | f | 0.5 | 0 | 7:3 | MeOH | 3.1 | I | 0.2 | 5 |
| Comparative Example 44 | B | 100 | g | 0.5 | 0 | 7:3 | MeOH | 3.1 | I | 0.2 | 5 |
| Comparative Example 45 | B | 100 | i | 0.5 | 0 | 7:3 | MeOH | 3.1 | I | 0.2 | 5 |
| Comparative Example 46 | B | 100 | j | 0.5 | 0 | 7:3 | MeOH | 3.1 | I | 0.2 | 5 |
| Comparative Example 47 | B | 100 | k | 0.5 | 0 | 7:3 | MeOH | 3.1 | I | 0.2 | 5 |
| Comparative Example 48 | B | 100 | l | 0.5 | 0 | 7:3 | MeOH | 3.1 | I | 0.2 | 5 |
| Comparative Example 49 | B | 100 | m | 0.5 | 0 | 7:3 | MeOH | 3.1 | I | 0.2 | 5 |
| Standard Sample 1 | D | 100 | n | 5 | 0 | 7:3 | MeOH | 1.0 | | | |
| Standard Sample 2 | D | 100 | n | 5 | 0 | 7:3 | MeOH | 3.1 | | | |
| Standard Sample 3 | D | 100 | n | 5 | 0 | 7:3 | MeOH | 3.1 | | | |
| Standard Sample 4 | D | 100 | n | 5 | 0 | 7:3 | MeOH | 3.1 | | | |
| Standard Sample 5 | D | 100 | n | 5 | 0 | 7:3 | MeOH | 3.1 | | | |

<Resin Composition>
Resin Composition A PEO:PEG = 80 parts by weight:20 parts by weight
Resin Composition B PEO:PEG = 20 parts by weight:80 parts by weight
Resin Composition C PEE:PEG = 20 parts by weight:80 parts by weight
Resin Composition D PEO 100 parts by weight
Resin Composition E PEO:PEG = 60 parts by weight:40 parts by weight
<Thermal Treatment Condition>
Thermal Treatment Condition F 50° C. one hour
Thermal Treatment Condition G 50° C. one week
Thermal Treatment Condition H 50° C. one month
Thermal Treatment Condition I 55° C. one week

TABLE 3

| | | | | | DSC | | | |
|---|---|---|---|---|---|---|---|---|
| | Hole Position Accuracy | | | | | | | Thermal |
| | Ave. + 3σ | | | | Untreated | | | Treated |
| | | Thermal | | Change | Solidifying | Solidifying | Degree | Solidifying |
| | Untreated | Treated | Δ | Ratio | Temperature | Calorie | of | Temperature |
| Classification | μm | μm | μm | % | ° C. | J/mg | Crystallinity | ° C. |
| Ex. 1 | 23.6 | 23.8 | 0.2 | 0.8 | 45.8 | −134 | 1.21 | 36.9 |
| Ex. 2 | 13.0 | 13.1 | 0.1 | 0.6 | 36.9 | −136 | 1.26 | 41.4 |
| Ex. 3 | 21.8 | 20.3 | −1.5 | −6.9 | 40.7 | −157 | 1.41 | 36.8 |
| Ex. 4 | 19.1 | 17.2 | −1.9 | −9.9 | 43.8 | −154 | 1.39 | 44.4 |
| Ex. 5 | 19.8 | 17.3 | −2.5 | −12.6 | 43.8 | −153 | 1.38 | 43.8 |
| Ex. 6 | 21.7 | 22.9 | 1.1 | 5.2 | 39.3 | −137 | 1.24 | 42.8 |
| Ex. 7 | 26.4 | 24.2 | −2.2 | −8.3 | 38.3 | −168 | 1.53 | 41.7 |
| Ex. 8 | 20.8 | 19.6 | −1.3 | −6.1 | 37.1 | −144 | 1.31 | 37.5 |
| Ex. 9 | 22.0 | 20.5 | −1.5 | −6.8 | 39.1 | −149 | 1.36 | 39.4 |
| Ex. 10 | 17.6 | 17.2 | −0.4 | −2.3 | 40.1 | −143 | 1.29 | 38.7 |
| Ex. 11 | 19.8 | 20.0 | 0.2 | 1.0 | 42.7 | −154 | 1.40 | 42.9 |
| Ex. 12 | 21.3 | 16.1 | −5.2 | −24.4 | 45.1 | −144 | 1.30 | 45.5 |
| Ex. 13 | 23.5 | 25.0 | 1.5 | 6.5 | 37.6 | −137 | 1.25 | 38.0 |
| Ex. 14 | 13.0 | 12.6 | −0.3 | −2.5 | 31.5 | −133 | 1.23 | 32.7 |
| Ex. 15 | 19.2 | 16.7 | −2.5 | −13.0 | 43.2 | −151 | 1.36 | 44.0 |
| Ex. 16 | 10.5 | 10.5 | 0.0 | −0.2 | 33.5 | −155 | 1.44 | 39.0 |
| Ex. 17 | 19.2 | 17.1 | −2.0 | −10.6 | 38.4 | −150 | 1.36 | 36.2 |
| Ex. 18 | 17.8 | 18.0 | 0.2 | 1.1 | 39.5 | −157 | 1.41 | 37.9 |
| Ex. 19 | 23.1 | 21.4 | −1.7 | −7.5 | 40.9 | −135 | 1.23 | 41.1 |
| Ex. 20 | 24.2 | 23.9 | −0.3 | −1.2 | 39.8 | −137 | 1.28 | 39.6 |
| Ex. 21 | 21.5 | 20.1 | −1.4 | −6.5 | 40.1 | −149 | 1.38 | 42.1 |
| Ex. 22 | 24.4 | 24.1 | −0.3 | −1.2 | 39.7 | −157 | 1.45 | 39.1 |
| Ex. 23 | 22.0 | 21.7 | −0.3 | −1.4 | 39.9 | −144 | 1.33 | 38.9 |
| Ex. 24 | 24.2 | 23.3 | −0.9 | −3.7 | 39.8 | −137 | 1.28 | 39.1 |
| Ex. 25 | 21.5 | 20.3 | −1.2 | −5.6 | 40.1 | −149 | 1.38 | 41.1 |
| Ex. 26 | 24.4 | 23.9 | −0.5 | −2.0 | 39.7 | −157 | 1.45 | 39.1 |
| Ex. 27 | 22.0 | 22.0 | 0 | 0.0 | 39.9 | −144 | 1.33 | 40.9 |
| Ex. 28 | 24.2 | 24.1 | −0.1 | −0.4 | 39.8 | −137 | 1.28 | 39.4 |
| Ex. 29 | 21.5 | 21.6 | 0.1 | 0.5 | 40.1 | −149 | 1.38 | 41.1 |
| Ex. 30 | 24.4 | 24.3 | −0.1 | −0.4 | 39.7 | −157 | 1.45 | 39.3 |
| Ex. 31 | 22.0 | 22.6 | 0.6 | 2.7 | 39.9 | −144 | 1.33 | 39.0 |
| Ex. 32 | 24.2 | 23.9 | −0.3 | −1.2 | 39.8 | −137 | 1.28 | 39.7 |
| Ex. 33 | 21.5 | 21.8 | 0.3 | 1.4 | 40.1 | −149 | 1.38 | 42.1 |
| Ex. 34 | 24.4 | 24.6 | 0.2 | 0.8 | 39.7 | −157 | 1.45 | 39.3 |
| Ex. 35 | 22.0 | 22.4 | 0.4 | 1.8 | 39.9 | −144 | 1.33 | 39.0 |
| CEx. 1 | 37.8 | 38.5 | 0.7 | 1.9 | 39.6 | −116 | 1.04 | 40.2 |
| CEx. 2 | 15.3 | 17.2 | 1.9 | 12.4 | 34.0 | −109 | 1.01 | 34.3 |
| CEx. 3 | 20.5 | 24.9 | 4.4 | 21.5 | 35.8 | −108 | 0.97 | 36.2 |
| CEx. 4 | 41.2 | 44.3 | 3.1 | 7.5 | 40.6 | −102 | 0.91 | 40.6 |
| CEx. 5 | 35.2 | 36.0 | 0.8 | 2.3 | 41.1 | −130 | 1.17 | 41.2 |
| CEx. 6 | 31.4 | 35.1 | 3.7 | 11.8 | 36.8 | −116 | 1.05 | 36.9 |
| CEx. 7 | 25.8 | 28.8 | 3.0 | 11.6 | 36.4 | −127 | 1.14 | 36.8 |
| CEx. 8 | 39.8 | 42.0 | 2.2 | 5.5 | 35.9 | −100 | 0.89 | 36.4 |
| CEx. 9 | 25.7 | 25.4 | −0.3 | −1.2 | 45.2 | −141 | 1.27 | 44.3 |
| CEx. 10 | 14.9 | 17.2 | 2.3 | 15.7 | 36.4 | −122 | 1.13 | 40.9 |
| CEx. 11 | 15.1 | 19.9 | 4.8 | 31.8 | 39.1 | −119 | 1.07 | 37.9 |
| CEx. 12 | 16.7 | 19.6 | 2.9 | 17.4 | 44.5 | −119 | 1.07 | 44.3 |
| CEx. 13 | 16.7 | 17.7 | 1.0 | 6.0 | 45.8 | −134 | 1.21 | 45.1 |
| CEx. 14 | 28.4 | 30.3 | 1.9 | 6.7 | 38.7 | −109 | 1.01 | 38.2 |
| CEx. 15 | 21.4 | 23.9 | 2.5 | 11.7 | 38.9 | −119 | 1.10 | 38.1 |
| CEx. 16 | Flat Sheet Not Obtained | | | | | | | |
| CEx. 17 | 22.2 | 26.2 | 4 | 18.0 | 39.9 | −126 | 1.17 | 39.1 |
| CEx. 18 | 20.4 | 23.6 | 3.2 | 15.7 | 43.8 | −138 | 1.28 | 43.1 |
| CEx. 19 | 22.4 | 25.0 | 2.6 | 11.6 | 42.8 | −146 | 1.35 | 42.2 |
| CEx. 20 | 20.9 | 23.7 | 2.8 | 13.4 | 43.8 | −152 | 1.41 | 43.3 |
| CEx. 21 | 15.8 | 19.3 | 3.5 | 22.2 | 45.1 | −130 | 1.20 | 46.1 |
| CEx. 22 | 29.2 | 29.5 | 0.3 | 1.0 | 38.1 | −107 | 0.99 | 38.7 |
| CEx. 23 | 28.4 | 31.5 | 3.1 | 10.9 | 38.7 | −109 | 1.01 | 38.2 |
| CEx. 24 | 21.4 | 24.5 | 3.1 | 14.5 | 38.9 | −119 | 1.10 | 38.1 |
| CEx. 25 | Flat Sheet Not Obtained | | | | | | | |
| CEx. 26 | 22.2 | 26.3 | 4.1 | 18.5 | 39.9 | −126 | 1.17 | 39.1 |
| CEx. 27 | 20.4 | 25.5 | 5.1 | 25.0 | 43.8 | −138 | 1.28 | 43.9 |
| CEx. 28 | 22.4 | 26.6 | 4.2 | 18.8 | 42.8 | −146 | 1.35 | 42.0 |
| CEx. 29 | 20.9 | 23.6 | 2.7 | 12.9 | 43.8 | −152 | 1.41 | 43.9 |
| CEx. 30 | 15.8 | 18.4 | 2.6 | 16.5 | 45.1 | −130 | 1.20 | 45.4 |
| CEx. 31 | 29.2 | 27.7 | −1.5 | −5.1 | 38.1 | −107 | 0.99 | 38.6 |
| CEx. 32 | 28.4 | 31.3 | 2.9 | 10.2 | 38.7 | −109 | 1.01 | 38.1 |
| CEx. 33 | 21.4 | 24.9 | 3.5 | 16.4 | 38.9 | −119 | 1.10 | 38.0 |
| CEx. 34 | Flat Sheet Not Obtained | | | | | | | |
| CEx. 35 | 22.2 | 26.3 | 4.1 | 18.5 | 39.9 | −126 | 1.17 | 39.3 |
| CEx. 36 | 20.4 | 25.3 | 4.9 | 24.0 | 43.8 | −138 | 1.28 | 43.1 |
| CEx. 37 | 22.4 | 25.2 | 2.8 | 12.5 | 42.8 | −146 | 1.35 | 42.1 |
| CEx. 38 | 20.9 | 23.1 | 2.2 | 10.5 | 43.8 | −152 | 1.41 | 43.5 |
| CEx. 39 | 15.8 | 23.9 | 8.1 | 51.3 | 45.1 | −130 | 1.20 | 45.0 |
| CEx. 40 | 29.2 | 28.7 | −0.5 | −1.7 | 38.1 | −107 | 0.99 | 38.9 |
| CEx. 41 | 28.4 | 29.9 | 1.5 | 5.3 | 38.7 | −109 | 1.01 | 38.0 |
| CEx. 42 | 21.4 | 29.8 | 8.4 | 39.3 | 38.9 | −119 | 1.10 | 38.6 |
| CEx. 43 | Flat Sheet Not Obtained | | | | | | | |
| CEx. 44 | 22.2 | 29.4 | 7.2 | 32.4 | 39.9 | −126 | 1.17 | 38.1 |
| CEx. 45 | 20.4 | 24.1 | 3.7 | 18.1 | 43.8 | −138 | 1.28 | 43.1 |
| CEx. 46 | 22.4 | 26.6 | 4.2 | 18.8 | 42.8 | −146 | 1.35 | 42.9 |
| CEx. 47 | 20.9 | 24.7 | 3.8 | 18.2 | 43.8 | −152 | 1.41 | 43.1 |
| CEx. 48 | 15.8 | 26.7 | 10.9 | 69.0 | 45.1 | −130 | 1.20 | 46.1 |
| CEx. 49 | 29.2 | 28.1 | −1.1 | −3.8 | 38.1 | −107 | 0.99 | 38.8 |

| | DSC | | Surface Hardness | | | | |
|---|---|---|---|---|---|---|---|
| | Thermal Treated | | Ave. | | σ | | |
| | Solidifying | Degree | | Thermal | | Thermal | |
| | Calorie | of | Untreated | Treated | Untreated | Treated | Comprehensive |
| Classification | J/mg | Crystallinity | N/mm² | N/mm² | N/mm² | N/mm² | Judgement |
| Ex. 1 | −136 | 1.23 | 14.2 | 15.9 | 0.45 | 0.43 | ◯Δ |
| Ex. 2 | −128 | 1.18 | 8.6 | 9.0 | 0.60 | 0.58 | [symbol] |
| Ex. 3 | −149 | 1.34 | 10.8 | 11.6 | 0.57 | 0.88 | [symbol] |
| Ex. 4 | −156 | 1.41 | 9.4 | 10.3 | 0.61 | 0.69 | ⊚ |
| Ex. 5 | −152 | 1.37 | 9.5 | 16.2 | 1.89 | 0.32 | ◯Δ |
| Ex. 6 | −139 | 1.27 | 24.1 | 20.8 | 2.00 | 1.86 | [symbol] Δ |
| Ex. 7 | −145 | 1.32 | 18.4 | 26.2 | 1.75 | 1.71 | [symbol] |
| Ex. 8 | −139 | 1.26 | 21.7 | 23.5 | 1.50 | 1.84 | [symbol] |
| Ex. 9 | −140 | 1.27 | 20.2 | 23.5 | 1.93 | 1.34 | ◯Δ |
| Ex. 10 | −136 | 1.23 | 9.6 | 10.5 | 0.72 | 0.59 | ◯ |
| Ex. 11 | −149 | 1.36 | 21.3 | 18.1 | 1.03 | 1.23 | ◯ |
| Ex. 12 | −144 | 1.30 | 16.7 | 15.3 | 0.41 | 0.29 | ◯ |
| Ex. 13 | −132 | 1.20 | 17.6 | 14.4 | 1.92 | 1.07 | ◯Δ |
| Ex. 14 | −124 | 1.15 | 12.1 | 10.6 | 0.93 | 0.78 | ◯ |
| Ex. 15 | −151 | 1.36 | 10.3 | 10.9 | 1.33 | 0.43 | ◯ |
| Ex. 16 | −145 | 1.34 | 11.9 | 9.4 | 1.44 | 1.13 | ◯ |
| Ex. 17 | −121 | 1.10 | 23.4 | 27.5 | 1.66 | 1.11 | ◯Δ |
| Ex. 18 | −159 | 1.43 | 10.1 | 10.3 | 0.49 | 1.10 | ◯ |
| Ex. 19 | −112 | 1.02 | 17.6 | 17.5 | 1.50 | 1.85 | ◯ |
| Ex. 20 | −131 | 1.21 | 18.8 | 18.5 | 0.47 | 1.85 | ◯Δ |
| Ex. 21 | −146 | 1.35 | 19.1 | 21.6 | 0.99 | 1.17 | [symbol] |
| Ex. 22 | −156 | 1.45 | 19.3 | 19.9 | 1.75 | 1.73 | [symbol] |
| Ex. 23 | −141 | 1.30 | 19.6 | 21.2 | 1.86 | 1.13 | [symbol] Δ |
| Ex. 24 | −139 | 1.29 | 18.8 | 18.3 | 0.47 | 1.72 | ◯Δ |
| Ex. 25 | −144 | 1.34 | 19.1 | 24.5 | 0.99 | 1.37 | ⊚ |
| Ex. 26 | −159 | 1.47 | 19.3 | 24.7 | 1.75 | 1.71 | ◯Δ |
| Ex. 27 | −142 | 1.31 | 19.6 | 18.7 | 1.86 | 1.30 | ◯Δ |
| Ex. 28 | −134 | 1.24 | 18.8 | 20.1 | 0.47 | 1.53 | ◯Δ |
| Ex. 29 | −135 | 1.25 | 19.1 | 23.6 | 0.99 | 1.81 | Δ |
| Ex. 30 | −152 | 1.41 | 19.3 | 23.4 | 1.75 | 2.71 | ◯Δ |
| Ex. 31 | −152 | 1.40 | 19.6 | 20.6 | 1.86 | 3.34 | ◯Δ |
| Ex. 32 | −131 | 1.21 | 18.8 | 19.6 | 0.47 | 1.78 | ◯Δ |
| Ex. 33 | −147 | 1.36 | 19.1 | 22.9 | 0.99 | 2.39 | ◯ |
| Ex. 34 | −156 | 1.45 | 19.3 | 23.3 | 1.75 | 2.15 | ◯Δ |
| Ex. 35 | −141 | 1.30 | 19.6 | 24.9 | 1.86 | 0.70 | ◯Δ |
| CEx. 1 | −118 | 1.05 | 15.3 | 8.7 | 1.03 | 0.92 | X |
| CEx. 2 | −93.2 | 0.86 | 7.6 | 7.7 | 2.33 | 2.32 | Δ |
| CEx. 3 | −107 | 0.96 | 6.1 | 6.6 | 2.10 | 2.42 | X |
| CEx. 4 | −96.5 | 0.86 | 13.9 | 6.5 | 0.39 | 0.63 | X |
| CEx. 5 | −128 | 1.15 | 9.8 | 11.2 | 2.00 | 0.21 | [symbol] |
| CEx. 6 | −119 | 1.07 | 6.7 | 7.4 | 0.25 | 0.28 | [symbol] |
| CEx. 7 | −111 | 1.00 | 17.6 | 8.8 | 2.10 | 0.45 | Δ |
| CEx. 8 | −101 | 0.90 | 14.6 | 11.6 | 1.21 | 0.54 | [symbol] |
| CEx. 9 | −132 | 1.19 | 12.5 | 15.1 | 0.79 | 0.49 | Δ |
| CEx. 10 | −106 | 0.98 | 21.7 | 25.2 | 2.28 | 2.53 | Δ |
| CEx. 11 | −113 | 1.02 | 5.8 | 7.1 | 2.17 | 2.07 | [symbol] |
| CEx. 12 | −127 | 1.14 | 8.9 | 7.8 | 2.17 | 2.28 | Δ |
| CEx. 13 | −144 | 1.30 | 11.0 | 7.3 | 2.36 | 0.71 | Δ |
| CEx. 14 | −101 | 0.94 | 21.4 | 22.3 | 3.36 | 3.03 | [symbol] |
| CEx. 15 | −116 | 1.08 | 17.0 | 19.1 | 2.59 | 2.76 | Δ |
| CEx. 16 | Flat Sheet Not Obtained | | | | | | XX |
| CEx. 17 | −123 | 1.14 | 12.4 | 16.9 | 2.19 | 2.29 | Δ |
| CEx. 18 | −126 | 1.17 | 20.6 | 14.7 | 3.38 | 2.18 | Δ |
| CEx. 19 | −135 | 1.25 | 14.1 | 19.1 | 2.95 | 3.04 | Δ |
| CEx. 20 | −146 | 1.35 | 17.8 | 20.8 | 2.40 | 2.27 | Δ |
| CEx. 21 | −132 | 1.22 | 20.7 | 27.7 | 2.18 | 3.04 | X |
| CEx. 22 | −106 | 0.98 | 16.2 | 17.2 | 1.82 | 1.57 | X |
| CEx. 23 | −110 | 1.02 | 21.4 | 21.1 | 3.36 | 2.90 | X |
| CEx. 24 | −120 | 1.11 | 17.0 | 22.8 | 2.59 | 3.32 | Δ |
| CEx. 25 | Flat Sheet Not Obtained | | | | | | XX |
| CEx. 26 | −132 | 1.22 | 12.4 | 12.6 | 2.19 | 2.63 | [symbol] |
| CEx. 27 | −139 | 1.29 | 20.6 | 13.5 | 3.38 | 1.91 | [symbol] |
| CEx. 28 | −142 | 1.31 | 14.1 | 20.4 | 2.95 | 2.67 | Δ |
| CEx. 29 | −150 | 1.39 | 17.8 | 24.3 | 2.40 | 2.58 | Δ |
| CEx. 30 | −122 | 1.13 | 20.7 | 22.1 | 2.18 | 2.39 | Δ |
| CEx. 31 | −101 | 0.94 | 16.2 | 15.1 | 1.82 | 1.75 | [symbol] |
| CEx. 32 | −108 | 1.00 | 21.4 | 18.9 | 3.36 | 3.34 | [symbol] |
| CEx. 33 | −110 | 1.02 | 17.0 | 24.4 | 2.59 | 4.20 | Δ |
| CEx. 34 | Flat Sheet Not Obtained | | | | | | XX |
| CEx. 35 | −131 | 1.21 | 12.4 | 20.6 | 2.19 | 3.48 | Δ |
| CEx. 36 | −132 | 1.22 | 20.6 | 20.8 | 3.38 | 2.56 | [symbol] |
| CEx. 37 | −142 | 1.31 | 14.1 | 19.6 | 2.95 | 4.93 | Δ |
| CEx. 38 | −150 | 1.39 | 17.8 | 24.4 | 2.40 | 3.95 | Δ |
| CEx. 39 | −122 | 1.13 | 20.7 | 20.0 | 2.18 | 1.56 | [symbol] |
| CEx. 40 | −104 | 0.96 | 16.2 | 16.9 | 1.82 | 1.29 | [symbol] |
| CEx. 41 | −104 | 0.96 | 21.4 | 24.1 | 3.36 | 4.70 | Δ |
| CEx. 42 | −110 | 1.02 | 17.0 | 18.0 | 2.59 | 3.72 | X |
| CEx. 43 | Flat Sheet Not Obtained | | | | | | XX |
| CEx. 44 | −120 | 1.11 | 12.4 | 18.8 | 2.19 | 3.37 | [symbol] |
| CEx. 45 | −136 | 1.26 | 20.6 | 18.6 | 3.38 | 3.29 | Δ |
| CEx. 46 | −141 | 1.30 | 14.1 | 18.4 | 2.95 | 2.99 | Δ |
| CEx. 47 | −146 | 1.35 | 17.8 | 15.8 | 2.40 | 3.51 | Δ |
| CEx. 48 | 120 | 1.11 | 20.7 | 21.3 | 2.18 | 2.47 | [symbol] |
| CEx. 49 | −103 | 0.95 | 16.2 | 17.2 | 1.82 | 1.11 | [symbol] |

| | DSC | | | |
|---|---|---|---|---|
| | Untreated | | After 50° C., 1 hr | |
| | Solidifying Calorie | | Solidifying Calorie | |
| Classification | J/mg | Degree of Crystallinity | J/mg | Degree of Crystallinity |
| Standard Sample 1 | −112 | 1.00 | −110 | 0.98 |
| Standard Sample 2 | −111 | 1.00 | −111 | 1.00 |
| Standard Sample 3 | −110 | 1.00 | −110 | 1.00 |
| Standard Sample 4 | −108 | 1.00 | −108 | 1.00 |
| Standard Sample 5 | −108 | 1.00 | −108 | 1.00 |

[symbol]

indicates data missing or illegible when filed

TABLE 4
Comprehensive Judgment Criteria

| | | Classification | | | | |
|---|---|---|---|---|---|---|
| | | Claim Requirement | | | Effect | |
| | | Thermal Deterioration Acceleration Test | | | | |
| | | Untreated | | | Thermal Treated | |
| | | Property | | | | |
| | | | | | Hole | |
| | | | | | Position | |
| | | | | | Accuracy | Hole |
| | | | Surface | | Change | Position |
| | | | Hardness | | Ratio | Accuracy |
| | | Degree of | (N/mm²) | | (%) | (μm) |
| Judgment | | Crystallinity | Ave. | σ | Ave. + 3σ | |
| ⊚ | Example | ≧1.3 | ≧8.5 | ≦1.0 | ≦0 | ≦21 |
| ◯ | | ≧1.2 | ≦25 | ≦1.5 | ≦.5 | ≦23 |
| ◯Δ | | ≧1.2 | | ≦2.0 | ≦+10 | ≦25 |
| Δ | Comparative | ≧1.0 | <8.5 | >2.0 | ≦+20 | ≦30 |
| X | Example | ≧0.9 | | | >+20 | >30 |
| XX | | <0.9 | | | | |

As shown in the above experiment examples, a linear unsaturated fatty acid salt, as compared to other additives, contributed to reduction of thermal deterioration of hole position accuracy or improvement of hole position accuracy, and had good comprehensive judgment. Further, among linear unsaturated fatty acid salts, ones using sodium oleate (thermal stabilizer (b)) were excellent in comprehensive judgment under any thermal treatment conditions. Also, the case of using a linear unsaturated fatty acid salt and sodium formate as a nucleating agent in combination had a special function effect of exhibiting stable and excellent hole position accuracy both before and after the above thermal deterioration acceleration test. Particularly, when a drill bit diameter becomes small, since hole position accuracy becomes easily influenced by the surface state of a water-soluble resin composition layer, the above function effect clearly shows. In other words, in order to promote high densification of a printed wiring board, making a drill bit to have a small diameter and a hole diameter to be small is essential, and therefore the invention of improving hole position accuracy is an important technique. In addition, as described above, a linear unsaturated fatty acid salt as a thermal stabilizer and sodium formate as a nucleating agent each has a particular added amount range necessary and sufficient for exhibiting a function effect, which should be set accordingly from a perspective of economical rationality. It should be noted that the sodium formate as a nucleating agent has a different function effect from the linear unsaturated fatty acid salt as a thermal stabilizer. For example, the case of not containing a linear unsaturated fatty acid salt but containing sodium formate in an entry sheet for drilling use, differently from the case of not containing sodium formate but containing a linear unsaturated fatty acid salt, tended to have a large standard deviation of surface hardness of the linear water-soluble resin composition layer (untreated). In addition, in Comparative Examples 16, 25, 34, 43 using sodium stearate (additive (f)), a solution of water-soluble resin composition swelled over time, a flat sheet usable as an entry sheet for drilling use could not be obtained.

<Evaluation Method>

1) Degree of Crystallinity

In the invention, as a method for measuring the degree of crystallinity of a water-soluble resin composition, a DSC (differential scanning calorimeter, DSC6220 manufactured by SII Nano technology Inc.) was used to the obtained water-soluble resin composition.

As the conditions, the temperature was risen from 30° C. to 100° C., then held at 100° C. for three minutes, next cooled from 100° C. to 30° C., then held at 30° C. for three minutes, and the temperature rising rate then was +3° C./min, and the cooling rate was −3° C./min. This cycle was conducted twice, and the solidifying calorie in the second temperature fall was calculated. In that regard, measurement was conducted using 10 mg of water-soluble resin composition sample, and the solidifying calorie per 1 mg of sample was calculated from the obtained data as the solidifying calorie of a water-soluble resin composition sample.

On the other hand, a standard resin composition (A) was 100 parts by weight of polyethylene oxide with a weight average molecular weight (Mw) of 110,000 (ALKOX L11 manufactured by Meisei Chemical Works, Ltd.) having 5 parts by weight of Red No. 2 added thereto. For the degree of crystallinity of the standard resin composition (A), the solidifying calorie in the second temperature fall was calculated using the same DSC, and this solidifying calorie was defined as a degree of crystallinity of 1.0.

Next, the above solidifying calorie of a water-soluble resin composition sample was divided by the solidifying calorie of the standard resin composition (A) to obtain the degree of crystallinity of a water-soluble resin composition sample.

Degree of crystallinity of sample=solidifying calorie of sample÷solidifying calorie of standard resin composition (A)

2) Solidifying Temperature

In the invention, for the conditions for measuring the solidifying temperature of a water-soluble resin composition, under the same condition as 1) degree of crystallinity, the peak top temperature of the exotherminc peak upon solidification in the second temperature fall was used as the solidifying temperature.

3) Surface Hardness

In the invention, for the surface hardness of a water-soluble resin composition layer, the surface hardness (Martens hardness) of a water-soluble resin composition layer was measured at optional 10 points, from vertically above an entry sheet for drilling, using a dynamic ultra-micro hardness tester (DUH-211, manufactured by Shimadzu Corporation), under conditions of penetrator: Triangular 115, sample force: 10 mN, loading rate: 0.7316 mN/sec, load holding time: 10 sec, Poisson ratio: 0.07. The average value and the standard deviation σ of the surface hardness obtained then were calculated.

4) Drilling

In the invention, for each sample, drilling was conducted under the following conditions.

An entry sheet for drilling use was disposed on the top of five superimposed copper clad laminated boards with a thickness of 0.2 mm (CCL-HL832, copper foil both surfaces 12 μm, manufactured by Mitsubishi Gas Chemical Company, Inc.) with a water-soluble resin composition layer facing up, a reinforcing board (bakelite board) was disposed on the downside of the superimposed copper clad laminated boards, and drilling was conducted by 3,000 hits per drill bit, under drilling conditions of drill bit: 0.2 mmφ (CFU020S manufactured by Tungaloy Corporation), rotation rate: 200,000 rpm, and feed rate: 2.6 m/min.

Also, an entry sheet for drilling use was disposed on the top of six superimposed copper clad laminated boards with a thickness of 0.1 mm (CCL-HL832NXA, copper foil both surfaces 3 μm, manufactured by Mitsubishi Gas Chemical Company, Inc.) with a water-soluble resin composition layer facing up, a reinforcing board (bakelite board) was disposed on the downside of the superimposed copper clad laminated boards, and drilling was conducted by 3,000 hits per drill bit, under conditions of drill bit: 0.105 mmφ (MD J492B 0.105×1.6, manufactured by Union Tool Co.), rotation rate: 200,000 rpm, and feed rate: 1.6 m/min.

5) Hole Position Accuracy

In the invention, for hole position accuracy of an entry sheet for drilling use, misalignment between hole positions of 3,000 hits on the back surface of the bottom board of the superimposed copper clad laminated boards and designated coordinates was measured with a hole analyzer (HA-1AM, manufactured by Hitachi Via Mechanics, Ltd.), and the average value and the standard deviation (σ) were calculated per drill bit to obtain the average value+3σ and the maximum value. Then, as hole position accuracy of the entire drilling, the average value of “average value+3σ” values of a drill bit was calculated and recorded. The formula for obtaining the hole position accuracy of the entire drilling is as follows.

$$Hole position accuracy of entire drilling ( μm ) = ( {\sum }_{i = 1}^{n} “ average value + 3 σ ” of a drill bit ) + number of drill bits ( n ) \qquad [ Formula 1 ]$$

What is claimed is:

1. An entry sheet for drilling use for a laminated board or a multi-layered board comprising a metallic support foil and a layer of water-soluble resin composition formed on at least one surface of the metallic support foil, wherein
the water-soluble resin composition comprises a water-soluble resin, a water-soluble lubricant and a linear unsaturated fatty acid salt,
the layer of water-soluble resin composition is formed by coating on the metallic support foil, a hot melt of the water-soluble resin composition, or coating on the metallic support foil, a solution containing the water-soluble resin composition and drying it, and then cooling it from a cooling start temperature of 120° C. to 160° C. to a cooling end temperature of 25° C. to 40° C. within 60 seconds at a cooling rate of not less than 1.5° C./sec,
the water-soluble resin composition has a degree of crystallinity of not less than 1.2, and
the layer of water-soluble resin composition has a standard deviation σ of surface hardness of not more than 2, and a surface hardness of not less than 8.5 N/mm² to not more than 25 N/mm².

2. An entry sheet for drilling use according to claim 1, wherein the linear unsaturated fatty acid salt has a carbon number of not less than 3 to not more than 20.

3. An entry sheet for drilling use according to claim 1, wherein the linear unsaturated fatty acid salt is one kind or more selected from the group consisting of a sorbic acid salt, an oleic acid salt and a linoleic acid salt.

4. An entry sheet for drilling use according to claim 1, wherein the linear unsaturated fatty acid salt is an alkali metal salt.

5. An entry sheet for drilling use according to claim 1, wherein the water-soluble resin composition is one kind or more selected from the group consisting of polyethylene oxide, polypropylene oxide, sodium polyacrylate, polyacrylamide, polyvinylpyrrolidone, a cellulose derivative, polytetramethylene glycol and a polyester of polyalkylene glycol, with a weight average molecular weight (Mw) of not less than 60,000 to not more than 400,000.

6. An entry sheet for drilling use according to claim 1, wherein the water-soluble lubricant is one kind or more selected from the group consisting of polyethylene glycol, polypropylene glycol, monoethers of polyoxyethylene, polyoxyethylene monostearate, polyoxyethylene sorbitan monostearate, polyglycerin monostearates, and a polyoxyethylene propylene copolymer, with a weight average molecular weight (Mw) of not less than 500 to not more than 25,000.

7. An entry sheet for drilling use according to claim 1, wherein in a total of 100 parts by weight of water-soluble resin mixture comprising the water-soluble resin and the water-soluble lubricant, the content of the water-soluble resin is 3 parts by weight to 80 parts by weight, and the content of the water-soluble lubricant is 20 parts by weight to 97 parts by weight.

8. An entry sheet for drilling use according to claim 1, wherein the added amount of the linear unsaturated fatty acid salt is not less than 0.01 parts by weight to not more than 20 parts by weight based on a total of 100 parts by weight of the water-soluble resin and the water-soluble lubricant.

9. An entry sheet for drilling use according to claim 1, wherein the water-soluble resin composition further contains sodium formate.

10. An entry sheet for drilling use according to claim 1, wherein the added amount of the sodium formate is not less than 0.01 parts by weight to not more than 1.5 parts by weight based on a total of 100 parts by weight of the water-soluble resin and the water-soluble lubricant.

11. An entry sheet for drilling use according to claim 1, wherein the water-soluble resin composition has a solidifying temperature of not less than 30° C. to not more than 70° C.

12. An entry sheet for drilling use according to claim 1, for use in drilling with a drill bit diameter of not less than 0.05 mmφ to not more than 0.3 mmφ, in drilling a laminated board or a multi-layered board.

13. An entry sheet for drilling use according to claim 1, wherein the metallic support foil has a thickness of not less than 0.05 mm to not more than 0.5 mm.

14. An entry sheet for drilling use according to claim 13, wherein the metallic support foil is an aluminum foil having a resin membrane with a thickness of 0.001 to 0.02 mm attached thereto.

15. An entry sheet for drilling use according to claim 1, wherein the layer of water-soluble resin composition has a thickness of not less than 0.01 mm to not more than 0.3 mm.
